(19) United States
(12) Patent Application Publication
(10) Pub. No.: US 2023/0068420 A1
(43) Pub. Date: Mar. 2, 2023

(54) FLUID PUMP HAVING A POLYVINYLIDENE FLUORIDE MEMBRANE

(71) Applicant: Facebook Technologies, LLC, Menlo Park, CA (US)

(72) Inventors: Emma Rae Mullen, Seattle, WA (US); Andrew John Ouderkirk, Kirkland, WA (US); Nagi Hosni Elabbasi, Southborough, MA (US)

(21) Appl. No.: 17/835,366

(22) Filed: Jun. 8, 2022

Related U.S. Application Data
(60) Provisional application No. 63/233,892, filed on Aug. 17, 2021.

(51) Int. Cl. F04B 43/04

(52) U.S. Cl. CPC F04B 43/046

(57) ABSTRACT

A fluid pump includes a housing defining a fluid chamber and a piezoelectric membrane located within the chamber and attached to the housing. The piezoelectric membrane may divide the fluid chamber into a first fluid cavity and a second fluid cavity such that the application of an electric field to the piezoelectric membrane and its resulting displacement may provide a force that drives fluid through the pump, e.g., from an inlet of the fluid chamber into the first fluid cavity and from the second fluid cavity to an outlet of the fluid chamber.

### CROSS-REFERENCE TO RELATED APPLICATION

This application claims the benefit of priority under 35 U.S.C. § 119(e) of U.S. Provisional Application No. 63/233,892, filed Aug. 17, 2021, the contents of which are incorporated herein by reference in their entirety.

### BRIEF DESCRIPTION OF THE DRAWINGS

The accompanying drawings illustrate a number of exemplary embodiments and are a part of the specification. Together with the following description, these drawings demonstrate and explain various principles of the present disclosure.

FIG. 1 is a flow chart of an example gel casting method for forming a PVDF polymer thin film having high electromechanical efficiency according to various embodiments.

FIG. 2 is a schematic illustration of an extrusion system for forming a piezoelectric polymer thin film according to certain embodiments.

FIG. 3 is a schematic view of an example thin film orientation system for manufacturing an anisotropic polymer thin film according to some embodiments.

FIG. 4 illustrates a roll-to-roll manufacturing configuration for conveying and orienting a polymer thin film according to certain embodiments.

FIG. 5 illustrates an embodiment of a calendering method for manufacturing a polymer thin film.

FIG. 6 is a schematic illustration of (A) a single layer piezoelectric polymer membrane, and (B) a multilayer piezoelectric polymer membrane according to various embodiments.

FIG. 7 shows a piezoelectric membrane incorporated into (A) a unimorph architecture, and (B) a bimorph architecture according to certain embodiments.

FIG. 8 is a cross-sectional schematic view of a fluid pump configured to be driven by an actuatable piezoelectric polymer membrane according to some embodiments.

FIG. 9 is a cross-sectional schematic view of a dual-chamber fluid pump at various stages of operation according to some embodiments.

FIG. 10 is a cross-sectional schematic view of a dual-chamber fluid pump including a piezoelectric membrane at different stages of operation according to further embodiments.

FIG. 11 is a cross-sectional schematic view of a fluid pump including a piezoelectric membrane according to some embodiments.

FIG. 12 is a cross-sectional schematic view of a single chamber fluid pump including a piezoelectric polymer membrane according to some embodiments.

FIG. 13 is a cross-sectional schematic view of a multi-chamber, multi-membrane fluid pump according to various embodiments.

FIG. 14 is a cross-sectional schematic view of a multi-chamber, single membrane fluid pump according to various embodiments.

FIG. 15 is a cross-sectional schematic view of a single chamber fluid pump including a piezoelectric polymer membrane according to further embodiments.

FIG. 16 is an illustration of exemplary augmented-reality glasses that may be used in connection with embodiments of this disclosure.

FIG. 17 is an illustration of an exemplary virtual-reality headset that may be used in connection with embodiments of this disclosure.

FIG. 18 is an illustration of exemplary haptic devices that may be used in connection with embodiments of this disclosure.

FIG. 19 is an illustration of an exemplary virtual-reality environment according to embodiments of this disclosure.

FIG. 20 is an illustration of an exemplary augmented-reality environment according to embodiments of this disclosure.

FIG. 21 is an illustration of an exemplary fluidic control system that may be used in connection with embodiments of this disclosure.

Throughout the drawings, identical reference characters and descriptions indicate similar, but not necessarily identical, elements. While the exemplary embodiments described herein are susceptible to various modifications and alternative forms, specific embodiments have been shown by way of example in the drawings and will be described in detail herein. However, the exemplary embodiments described herein are not intended to be limited to the particular forms disclosed. Rather, the present disclosure covers all modifications, equivalents, and alternatives falling within the scope of the appended claims.

### DETAILED DESCRIPTION OF EXEMPLARY EMBODIMENTS

Polymer materials may be incorporated into a variety of different optic and electro-optic systems, including active and passive optics and electroactive devices. Lightweight and conformable, one or more polymer layers may be incorporated into wearable devices such as smart glasses and are attractive candidates for emerging technologies including virtual reality/augmented reality devices where a comfortable, adjustable form factor is desired.

Virtual reality (VR) and augmented reality (AR) eyewear devices or headsets, for instance, may enable users to experience events, such as interactions with people in a computer-generated simulation of a three-dimensional world or viewing data superimposed on a real-world view. By way of example, superimposing information onto a field of view may be achieved through an optical head-mounted display (OHMD) or by using embedded wireless glasses with a transparent heads-up display (HUD) or augmented reality (AR) overlay. VR/AR eyewear devices and headsets may be used for a variety of purposes. Governments may use such devices for military training, medical professionals may use such devices to simulate surgery, and engineers may use such devices as design visualization aids.

These and other applications may leverage one or more characteristics of thin film polymer materials, including piezoelectric properties to induce deformations and the refractive index to manipulate light. In various applications, optical elements and other components may include polymer thin films that have anisotropic mechanical and/or optical properties. The degree of optical or mechanical anisotropy achievable through conventional thin film manufacturing processes is typically limited, however, and is often exchanged for competing thin film properties such as flatness, toughness and/or film strength. For example, highly anisotropic polymer thin films often exhibit low strength in one or more in-plane direction, which may challenge manufacturability and limit performance.

As disclosed herein, some embodiments relate to haptic feedback devices that may be configured to represent virtual objects in contact with a person in an augmented reality space. Example haptic feedback devices can be implemented as an interactive device such as a keyboard or a touchpad, or as a wearable device, such as a glove or other wearable form factor configured to convey haptic information to the user. In AR systems, for instance, computer graphics can be merged with actual imagery in real time for display to a user. Furthermore, the scope of AR has expanded recently to include non-visual augmentation, such as haptic feedback. In this vein, various systems have been proposed for integrating haptic information into VR/AR, but such systems are typically complicated or limited to simple vibrational interactions. Notwithstanding recent developments, it would be advantageous to offer variable VR/AR systems that provide, for example, interactive haptic stimulation in a wearable form factor.

Various haptic systems may include fluid pumps for directing fluid flow. Microfluidic pumps, for instance, may be used to pump fluid (e.g., air, water, etc.) for haptic systems having small spaces, low flow rates, and/or low pressures. A piezoelectric microfluidic pump may include a piezoelectric element (e.g., membrane) that is reversibly displaceable by an oscillating electric field to force fluid through the pump.

The present disclosure is thus generally directed to fluid pumps and pump systems, including microfluidic pump systems. The fluid pumps may be incorporated into haptic as well as non-haptic systems. Non-haptic systems may be applied to biomedicine, fuel supply, liquid cooling, chemical processing, aerospace, and precision driving, for example. In some embodiments, the present disclosure relates to microfluidic pump systems that include a piezoelectric membrane. Example piezoelectric membranes include polymer compositions such as polyvinylidene fluoride (PVDF). Relative to comparative inactive membrane materials, an electroactive PVDF polymer material may be configured both as a membrane and as an active element, thus decreasing design complexity. PVDF polymer membranes may be advantageously light weight, mechanically durable, chemically inert, optically transparent, free of lead and other heavy metal constituents, actuated to higher strains/displacements, thermally compatible with other pump components, and economical to manufacture.

According to exemplary embodiments, a PVDF membrane may be characterized by an isotropic Young's modulus of 1 GPa or higher, or an anisotropic Young's modulus of at least approximately 2 GPa along at least one crystallographic axis. For instance, an anisotropic PVDF membrane may be characterized by a first in-plane Young's modulus along one crystal axis of at least approximately 1 GPa and a second in-plane Young's modulus along a second, orthogonal crystal axis of at least approximately 2 GPa.

Thus, various embodiments relate to fluid pumps having a PVDF-containing membrane. Such fluid pumps may be operable through the reverse piezoelectric effect, where contraction or expansion of the PVDF membrane may be achieved by the application of an electric field to the membrane. The attendant deformation of the membrane may exert a force on a pump fluid that is effective to force the fluid through the pump.

The piezoelectric response of a polymer thin film may be determined by its chemical composition, the chemical structure of the polymer repeat unit, its density and extent of crystallinity, as well as the alignment of the crystals and/or polymer chains. Among these factors, the crystal or polymer chain alignment may dominate. In crystalline or semi-crystalline polymer thin films, the piezoelectric response may be correlated to the degree or extent of crystal orientation, whereas the degree or extent of chain alignment may create comparable piezoelectric response in an amorphous phase within a polymer thin film.

An applied stress may be used to create a preferred alignment of crystals or polymer chains within a polymer thin film and induce a corresponding modification of the piezoelectric response along different directions of the film. As disclosed further herein, during processing where a polymer thin film is stretched to induce a preferred alignment of crystals/polymer chains and an attendant modification of the piezoelectric response, Applicants have shown that various casting methods and the choice of an associated liquid solvent can influence the piezoelectric properties of the cast thin film.

In accordance with particular embodiments, Applicants have developed a polymer thin film manufacturing method for forming a PVDF-based polymer thin film having a desired piezoelectric response. Whereas in PVDF and related polymers, the total extent of crystallization as well as the alignment of crystals may be limited due to polymer chain entanglement, as disclosed herein a casting method may facilitate the disentanglement and alignment of polymer chains, which may lead to improvements in the piezoelectric response of a polymer thin film.

The term “entanglement” generally refers to a measure of the degree of the reticular or spherical structure formed by the cross-linking points within a polymer chain or in between polymer chains. The extent of entanglement may affect the nature of the polymer. Normalizing to a polymer with a high degree of entanglement, a low entanglement polymer with a similar molecular weight and molecular weight polydispersity may have 50% or less of the entanglement, e.g., 50%, 20%, 10%, or 5%, including ranges between any of the foregoing values.

Methods of forming a piezoelectric polymer thin film or membrane include melt extrusion, solvent casting, and gel casting from a polymer solution. A polymer solution may include one or more crystallizable polymers, one or more additives, and one or more liquid solvents. A gel casting process, for instance, may provide control of one or more of the polymer composition and concentration, choice and concentration of liquid solvent, and casting temperature, and may facilitate decreased entanglement of polymer chains and allow the polymer film to achieve a higher stretch ratio during a later deformation step. In some cases, one or more low molecular weight additives may be added to the polymer solution and may encourage chain disentanglement. The molecular weight distribution of the one or more crystallizable polymers and the one or more additives may be respectively mono-disperse, bimodal, or polydisperse.

PVDF-based polymer thin films may be formed using a crystallizable polymer. Example crystallizable polymers may include moieties such as vinylidene fluoride (VDF), trifluoroethylene (TrFE), chlorofluoroethylene (CFE), chlorotrifluoroethylene (CTFE), hexafluoropropene (HFP), and vinyl fluoride (VF), as well as homopolymers, co-polymers, tri-polymers, derivatives, and combinations thereof. Example piezoelectric polymers include poly(vinylidene fluoride-co-trifluoroethylene) (PVDF-TrFE)), poly(vinylidene fluoride-trifluoroethylene-chlorofluoroethylene (P(VDF-TrFE-CFE)), and poly(vinylidenefluoride-trifluoroethylene-chlorotrifluoroethylene (P(VDF-TrFE-CTFE)), as well as mixtures thereof.

As used herein, one or more of the foregoing “PVDF-family” moieties may be combined with a low molecular weight additive to form an anisotropic polymer thin film. Reference herein to a PVDF thin film includes reference to any PVDF-family member-containing polymer thin film unless the context clearly indicates otherwise.

The crystallizable polymer component of such a PVDF thin film may have a molecular weight (“high molecular weight”) of at least approximately 100,000 g/mol, e.g., at least approximately 100,000 g/mol, at least approximately 150,000 g/mol, at least approximately 200,000 g/mol, at least approximately 250,000 g/mol, at least approximately 300,000 g/mol, at least approximately 350,000 g/mol, at least approximately 400,000 g/mol, at least approximately 450,000 g/mol, or at least approximately 500,000 g/mol, including ranges between any of the foregoing values.

If provided, a “low molecular weight” additive may have a molecular weight of less than approximately 200,000 g/mol, e.g., less than approximately 200,000 g/mol, less than approximately 100,000 g/mol, less than approximately 50,000 g/mol, less than approximately 25,000 g/mol, less than approximately 10,000 g/mol, less than approximately 5000 g/mol, less than approximately 2000 g/mol, less than approximately 1000 g/mol, less than approximately 500 g/mol, less than approximately 200 g/mol, or less than approximately 100 g/mol, including ranges between any of the foregoing values.

Example low molecular weight additives may include oligomers and polymers of vinylidene fluoride (VDF), trifluoroethylene (TrFE), chlorotrifluoroethylene (CTFE), hexafluoropropene (HFP), and vinyl fluoride (VF), as well as homopolymers, co-polymers, tri-polymers, derivatives, and combinations thereof. Such additives may be readily soluble in, and provide refractive index matching with, the high molecular weight component. For example, a low molecular weight additive may have a refractive index measured at 652.9 nm of from approximately 1.38 to approximately 1.55.

The molecular weight of the low molecular weight additive may be less than the molecular weight of the crystallizable polymer. According to one example, the crystallizable polymer may have a molecular weight of at least approximately 100,000 g/mol and the additive may have a molecular weight of less than approximately 25,000 g/mol. According to a further example, the crystallizable polymer may have a molecular weight of at least approximately 300,000 g/mol and the additive may have a molecular weight of less than approximately 200,000 g/mol. According to a particular example, the crystallizable polymer may have a molecular weight of approximately 600,000 g/mol and the additive may have a molecular weight of approximately 150,000 g/mol. Use herein of the term molecular weight may, in some examples, refer to a weight average molecular weight.

Generally, a low molecular weight additive may constitute up to approximately 90 wt. % of the polymer thin film, e.g., approximately 0.001 wt. %, approximately 0.002 wt. %, approximately 0.005 wt. %, approximately 0.01 wt. %, approximately 0.02 wt. %, approximately 0.05 wt. %, approximately 0.1 wt. %, approximately 0.2 wt. %, approximately 0.5 wt. %, approximately 1 wt. %, approximately 2 wt. %, approximately 5 wt. %, approximately 10 wt. %, approximately 20 wt. %, approximately 30 wt. %, approximately 40 wt. %, approximately 50 wt. %, approximately 60 wt. %, approximately 70 wt. %, approximately 80 wt. %, or approximately 90 wt. %, including ranges between any of the foregoing values.

In connection with some embodiments, an inorganic additive may be incorporated into the polymer thin film. Example inorganic additives may include barium titanate, barium strontium titanate, carbon nanotubes such as multi-walled carbon nanotubes (MWNTs), and the like, which may be provided in powder or fiber form. The average particle size of an inorganic additive may be less than approximately 1 micrometer, e.g., less than approximately 500 nm, less than approximately 200 nm, or less than approximately 100 nm, including ranges between any of the foregoing values. Such additives may increase the dielectric constant and/or the breakdown strength of the membrane, thereby improving dielectric performance. The amount of an inorganic additive may range from approximately 0.001 wt. % to approximately 5 wt. % of the polymer thin film, e.g., approximately 0.001 wt. %, approximately 0.002 wt. %, approximately 0.005 wt. %, approximately 0.01 wt. %, approximately 0.02 wt. %, approximately 0.05 wt. %, approximately 0.1 wt. %, approximately 0.2 wt. %, including ranges between any of the foregoing values.

The choice of liquid solvent may affect the maximum crystallinity and percent beta phase content of a PVDF-based polymer thin film. In addition, the polarity of the solvent may impact the critical polymer concentration (c*) for polymer chains to entangle in solution. The liquid solvent (i.e., “solvent”) may include a single solvent composition or a mixture of different solvents. In some embodiments, the solubility of the crystallizable polymer in the liquid solvent may be at least approximately 0.1 g/100 g (e.g., 1 g/100 g or 10 g/100 g) at a temperature of approximately 25° C. or more (e.g., 50° C., 75° C., 100° C., or 150° C.).

Example liquid solvents include, but are not limited to, dimethylformamide (DMF), cyclohexanone, dimethylacetamide (DMAc), diacetone alcohol, di-isobutyl ketone, tetramethyl urea, ethyl acetoacetate, dimethyl sulfoxide (DMSO), trimethyl phosphate, N-methyl-2-pyrrolidone (NMP), butyrolactone, isophorone, triethyl phosphate, carbitol acetate, propylene carbonate, glyceryl triacetate, dimethyl phthalate, acetone, tetrahydrofuran (THF), methyl ethyl ketone, methyl isobutyl ketone, glycol ethers, glycol ether esters, and N-butyl acetate.

A polymer gel may be obtained from the polymer solution by evaporating the solvent, cooling the polymer solution, adding a relatively poor solvent to the polymer solution, or a combination thereof. The solubility of the crystalline polymer in a poor solvent may be less than 20 g/100 g, e.g., 5 g/100 g or 1 g/100 g at a temperature of less than approximately 150° C., e.g., 75° C., 25° C., 0° C., −40° C., or −70° C. The polymer gel, which includes a mixture of the crystallizable polymer and the liquid solvent, may be transparent, translucent, or opaque. Following gelation, a polymer gel may be washed with a secondary solvent, which may replace the original solvent. A solvent evaporation step may be used to partially or completely remove the original solvent and/or the secondary solvent.

An anisotropic polymer thin film may be formed by applying a stress to the polymer gel, i.e., a polymer thin film containing the polymer gel. According to some examples, a solid state extrusion process may be used to orient the polymer chains and form a polymer thin film. According to further examples, a calendering process may be used to orient polymer chains in the gel at room temperature or at elevated temperature. The liquid solvent may be partially or fully removed before, during, or after stretching and orienting. Stretching and the associated chain/crystal alignment may be followed by poling to form a polymer thin film having a high electromechanical efficiency.

A calendering process may be applied to the dried or partially dried gel before stretching. The gel may be calendered several times with a progressively decreasing roller gap to achieve a target thickness. During the calendering process, any residual liquid solvent may be removed. The calendering process can be performed at room temperature and/or at a temperature no higher than approximately 150° C., e.g., 130° C., 110° C., 90° C., 70° C., or 50° C. The polymer may be stretched to a stretch ratio of at least approximately 1.5, e.g., 2, 2.5, 3, 3.5, 4, 4.5, 5, 5.5, 6, 7, 8, 9, 10, 15, 20, 30, or 50, including ranges between any of the foregoing values.

In an example process, a dried or substantially dried polymer material may be hot pressed to form a desired shape that is fed through a solid state extrusion system (i.e., extruder) at a suitable extrusion temperature. A solid state extruder may include a bifurcated nozzle, for example. The temperature for hot pressing and the extrusion temperature may each be less than approximately 190° C. That is, the hot pressing temperature and the extrusion temperature may be independently selected from 180° C., 170° C., 160° C., 150° C., 140° C., 130° C., 120° C., 110° C., 100° C., 90° C., or 80° C., including ranges between any of the foregoing values. According to particular embodiments, the extruded polymer material may be stretched further, e.g., using a post-extrusion, uniaxial or biaxial stretch process.

Stretching may include a single act of stretching or plural, successive stretching events, such as along different in-plane directions of a polymer thin film. The act(s) of stretching may be velocity limited or strain rate limited. In some embodiments, a polymer thin film may be stretched at a variable or constant velocity. In some embodiments, the polymer thin film may be stretched using a variable strain rate or a constant strain rate (e.g., 0.5/sec, 1/sec, 5/sec, or 10/sec, including ranges between any of the foregoing values). By way of example, the strain rate may decrease throughout an act of stretching and/or amongst different stretching events from an initial strain rate (e.g., 5/sec) to a final strain rate (e.g., 0.5/sec).

Some stretching processes may include two successive stretching events. For instance, orthogonal consecutive stretching (OCS) may be used to develop structural fingerprints, such as smaller lamellar thicknesses and higher degrees of polymer chain orientation at draw ratios less than the draw ratios used to achieve similar structural fingerprints via comparative single stretching (SS) or parallel consecutive stretching (PCS) techniques. Orthogonal consecutive stretching may include first stretching a polymer thin film along a first in-plane axis, and then subsequently stretching the polymer thin film along a second in-plane axis that is orthogonal to the first in-plane axis.

In an example method, a cast polymer thin film may be stretched along a first in-plane axis to a stretch ratio of up to approximately 4 (e.g., 2, 3, or 4, including ranges between any of the foregoing values) with an attendant relaxation in the cross-stretch direction having a relaxation ratio of at least approximately 0.2 (e.g., 0.2, 0.3, 0.4, or 0.5, including ranges between any of the foregoing values). Subsequently, the polymer thin film may be stretched along a second in-plane axis orthogonal to the first in-plane axis to a stretch ratio of at least approximately 7 (e.g., 7, 10, 20, 30, 40, 50, or 60, including ranges between any of the foregoing values) with a relaxation ratio in the cross-stretch direction of at least approximately 0.2 (e.g., 0.2, 0.3, 0.4, or 0.5, including ranges between any of the foregoing values).

In some examples, the draw ratio in the first stretching step may be less than the draw ratio in the second stretching step. According to further embodiments, the temperature of the polymer thin film during the second stretching step may be greater than the polymer thin film temperature during the first stretching step. The temperature during the second stretching step may be at least approximately 5° C. greater than the temperature during the first stretching step (e.g., 5, 10, 15, or 20° C. greater, including ranges between any of the foregoing values).

In some embodiments, a polymer thin film may be heated and stretched along a first direction, cooled, and then heated and stretched along a second direction. In some embodiments, a polymer thin film may be heated and stretched along a first direction, cooled, and then heated and stretched again along the first direction. Following the second stretching step, the polymer thin film may be cooled. The acts of cooling may immediately follow the first (or second) stretching steps, where the polymer thin film may be cooled within approximately 10 seconds following completion of the first (or second) stretching step.

Cooling may stabilize the microstructure of the stretched polymer thin film. In some examples, the temperature of the polymer thin film during an act of stretching may be greater than the glass transition temperature of the crystallizable polymer. In some examples, the temperature of the polymer thin film during an act of stretching may be less than, equal to, or greater than the melting onset temperature of the crystallizable polymer.

In various examples, the extent of relaxation perpendicular to the stretch direction may be approximately equal to the square root of the stretch ratio in the stretch direction. In some embodiments, the extent of relaxation may be substantially constant throughout the stretching process(es). In further embodiments, the extent of relaxation may decrease, with greater relaxation associated with the beginning of a stretch step and lesser relaxation associated with the end of a stretch step.

After extrusion or calendaring, a PVDF film may be oriented either uniaxially or biaxially as a single layer or multilayer to form a mechanically anisotropic and, in some embodiments, optically clear thin film. An anisotropic polymer thin film may be formed using a thin film orientation system configured to heat and stretch a polymer thin film in at least one in-plane direction in one or more distinct regions thereof. In some embodiments, a thin film orientation system may be configured to stretch a polymer thin film, i.e., a crystallizable polymer thin film, along only one in-plane direction. For instance, a thin film orientation system may be configured to apply an in-plane stress to a polymer thin film along the x-direction while allowing the thin film to relax along an orthogonal in-plane direction (e.g., along the y-direction). As used herein, the relaxation of a polymer thin film may, in certain examples, accompany the absence of an applied stress along the relaxation direction.

According to some embodiments, within an example orientation system, a polymer thin film may be heated and stretched transversely to a direction of film travel through the system. In such embodiments, a polymer thin film may be held along opposing edges by plural movable clips slidably disposed along a diverging track system such that the polymer thin film is stretched in a transverse direction (TD) as it moves along a machine direction (MD) through heating and deformation zones of the thin film orientation system. In some embodiments, the stretching rate in the transverse direction and the relaxation rate in the machine direction may be independently and locally controlled. In certain embodiments, large scale production may be enabled, for example, using a roll-to-roll manufacturing platform.

In certain aspects, the tensile stress may be applied uniformly or non-uniformly along a lengthwise or widthwise dimension of the polymer thin film. Heating of the polymer thin film may accompany the application of the tensile stress. For instance, a semi-crystalline polymer thin film may be heated to a temperature greater than room temperature (˜23° C.) to facilitate deformation of the thin film and the formation and realignment of crystals and/or polymer chains therein.

The temperature of the polymer thin film may be maintained at a desired value or within a desired range before, during and/or after the act of stretching, i.e., within a pre-heating zone or a deformation zone downstream of the pre-heating zone, in order to improve the deformability of the polymer thin film relative to an un-heated polymer thin film. The temperature of the polymer thin film within a deformation zone may be less than, equal to, or greater than the temperature of the polymer thin film within a pre-heating zone.

In some embodiments, the polymer thin film may be heated to a constant temperature throughout the act of stretching. In some embodiments, a region of the polymer thin film may be heated to different temperatures, i.e., during and/or subsequent to the application of a tensile stress. In some embodiments, different regions of the polymer thin film may be heated to different temperatures. In certain embodiments, the strain realized in response to the applied tensile stress may be at least approximately 20%, e.g., approximately 20%, approximately 50%, approximately 100%, approximately 200%, approximately 400%, approximately 500%, approximately 1000%, approximately 2000%, approximately 3000%, or approximately 4000% or more, including ranges between any of the foregoing values.

Following the act(s) of stretching, one or more thin film properties may be refined through hot pressing or hot calendering. Uniaxial hot pressing, for example, may be performed in a rigid die with loading applied along a common axis. Some pressing systems may include a graphite die, which may be enclosed in a protective atmosphere or vacuum chamber. During hot pressing, temperature and pressure may be applied simultaneously to the stretched polymer thin film. Heating may be achieved using induction coils that surround the graphite die, and pressure may be applied hydraulically. Hot calendering is a process of compressing a thin film during production by passing a polymer thin film between one or more pairs of heated rollers.

In some embodiments, a stretched polymer thin film may be pressed or calendered to at least approximately 50% of its initial thickness (e.g., 50%, 60%, 70%, or 80% of its initial thickness, including ranges between any of the foregoing values) under an applied pressure of at least approximately 2 MPa (e.g., 2, 3, 4, 5, or 10 MPa, including ranges between any of the foregoing values) and at a temperature of less than approximately 140° C. (e.g., 120° C., 125° C., 130° C., or 135° C., including ranges between any of the foregoing values).

A pressed or calendered polymer thin film may have a thickness of less than approximately 500 micrometers, e.g., less than 400 micrometers, less than 300 micrometers, or less than 200 micrometers. According to some embodiments, following hot pressing or hot calendering, a polymer thin film may be stretched further using one or more additional stretching steps. In a post-hot pressing or post-hot calendering stretching step, a polymer thin film may be stretched to a draw ratio of approximately 5 or greater (e.g., 5, 10, 20, 40, 60, 80, 100, 120, or 140, including ranges between any of the foregoing values).

Hot pressing or hot calendering may increase the transmissivity and/or the piezoelectric coefficient of a polymer thin film. According to some embodiments, the applied pressure may collapse voids within the polymer thin film, thus decreasing the overall void volume and increasing the density of the polymer matrix.

Following deformation of the polymer thin film, the heating may be maintained for a predetermined amount of time, followed by cooling of the polymer thin film. The act of cooling may include allowing the polymer thin film to cool naturally, at a set cooling rate, or by quenching, such as by purging with a low temperature gas, which may thermally stabilize the polymer thin film.

Following deformation, the crystals or chains may be at least partially aligned with the direction of the applied tensile stress. As such, a polymer thin film may exhibit a high degree of optical clarity and mechanical anisotropy.

The presently disclosed anisotropic PVDF-based polymer thin films may be characterized as optical quality polymer thin films and may form, or be incorporated into, an optical element such as an actuatable layer. Optical elements may be used in various display devices, such as virtual reality (VR) and augmented reality (AR) glasses and headsets. The efficiency of these and other optical elements may depend on the degree of optical clarity and/or piezoelectric response.

According to various embodiments, an “optical quality” thin film may, in some examples, be characterized by a transmissivity within the visible light spectrum of at least approximately 20%, e.g., 20, 30, 40, 50, 60, 70, 80, 90 or 95%, including ranges between any of the foregoing values, and less than approximately 10% bulk haze, e.g., 0, 1, 2, 4, 6, or 8% bulk haze, including ranges between any of the foregoing values. Transparent materials will typically exhibit very low optical absorption and minimal optical scattering.

As used herein, the terms “haze” and “clarity” may refer to an optical phenomenon associated with the transmission of light through a material, and may be attributed, for example, to the refraction of light within the material, e.g., due to secondary phases or porosity and/or the reflection of light from one or more surfaces of the material. As will be appreciated by those skilled in the art, haze may be associated with an amount of light that is subject to wide angle scattering (i.e., at an angle greater than 2.5° from normal) and a corresponding loss of transmissive contrast, whereas clarity may relate to an amount of light that is subject to narrow angle scattering (i.e., at an angle less than 2.5° from normal) and an attendant loss of optical sharpness or “see through quality.”

In further embodiments, a PVDF-based polymer thin film may be incorporated into a multilayer structure, such as the “A” layer in an ABAB multilayer. Further multilayer architectures may include AB, ABA, or ABC configurations. Each B layer (and each C layer, if provided) may include a further polymer composition, such as polyethylene. According to some embodiments, the B (and C) layer(s) may be electrically conductive and may include, for example, indium tin oxide (ITO) or poly(3,4-ethylenedioxythiophene). In example multilayer architectures, adjacent polymer layers may be bonded together using an adhesive layer. An adhesive layer may be configured to provide good adhesion between neighboring layers.

In example multilayer structures, neighboring anisotropic thin films may be misoriented by an in-plane angle of at least approximately 2°, e.g., 2, 5, 10, 15, 20, 25, 30, 35, 40, or 45°, including ranges between any of the foregoing values. Misorientation of the crystal axes of plural polymer thin films within a multilayer membrane may be used to control the net piezoelectric response of the membrane.

Example membranes may be configured as actuatable layers having a unimorph or bimorph construction. A unimorph or monomorph is a cantilever that includes one active (piezoelectric) layer and one inactive layer. Deformation in the piezoelectric layer may be induced by the application of an electric field. This deformation may create a bending displacement in the cantilever. In a unimorph actuator, the inactive layer may be fabricated from a non-piezoelectric material. A bimorph actuator, on the other hand, is a cantilever that includes two active layers. In some embodiments, a bimorph actuator may include a passive layer located between the two active layers. A bimorph actuator may include a serial configuration or a parallel configuration. During use, in response to an applied voltage, one active layer may contract while the other active layer may expand, thus creating a bending displacement.

In a single layer or multilayer architecture, each PVDF-family layer may have a thickness ranging from approximately 100 nm to approximately 5 mm, e.g., 100, 200, 500, 1000, 2000, 5000, 10000, 20000, 50000, 100000, 200000, 500000, 1000000, 2000000, or 5000000 nm, including ranges between any of the foregoing values. A multilayer stack may include two or more such layers. In some embodiments, a density of a PVDF layer or thin film may range from approximately 1.7 g/cm³ to approximately 1.9 g/cm³, e.g., 1.7, 1.75, 1.8, 1.85, or 1.9 g/cm³, including ranges between any of the foregoing values.

According to some embodiments, the areal dimensions (i.e., length and width) of an anisotropic PVDF-family polymer thin film may independently range from approximately 1 cm to approximately 50 cm or more, e.g., 1, 2, 5, 10, 20, 30, 40, or 50 cm, including ranges between any of the foregoing values. Example anisotropic polymer thin films may have areal dimensions of approximately 5 cm×5 cm, 10 cm×10 cm, 20 cm×20 cm, 50 cm×50 cm, 5 cm×10 cm, 10 cm×20 cm, 10 cm×50 cm, etc.

As used herein, the terms “polymer thin film” and “polymer layer” may be used interchangeably. Furthermore, reference to a “polymer thin film” or a “polymer layer” may include reference to a “multilayer polymer thin film” unless the context clearly indicates otherwise.

In accordance with various embodiments, a polymer composition used to form an anisotropic polymer thin film may include a crystallizable polymer and a low molecular weight additive. Without wishing to be bound by theory, one or more low molecular weight additives may interact with high molecular weight polymers throughout casting and stretch processes to facilitate less chain entanglement and better chain alignment and, in some examples, create a higher crystalline content within the polymer thin film.

Typical molecular weight and stretch ratios may limit the modulus of elasticity achieved by PVDF membranes. The systems and methods disclosed herein may address this limitation by causing the piezoelectric response of PVDF (and its copolymers) to be substantially increased by processing high and ultrahigh molecular weight moieties with high stretch ratios, and optionally by using cast polymer films with low entanglement. In some examples, a processing additive may be used to decrease chain entanglement and/or decrease surface roughness. These systems and methods may create a PVDF membrane having high modulus and strength, high piezoelectric response, and optionally high optical transparency.

In some examples, a composition having a bimodal molecular weight distribution may be cast to form a thin film, which may be stretched to induce mechanical and piezoelectric anisotropy through crystal and/or chain realignment. Stretching may include the application of a uniaxial stress or a biaxial stress. In some embodiments, the application of an in-plane biaxial stress may be performed simultaneously or sequentially. In some embodiments, the low molecular weight additive may beneficially decrease the stretching temperature needed to achieve crystal and/or chain realignment. In some embodiments, a polymer thin film may be stretched by calendering, solid state extrusion, and/or a combination of thereof.

In accordance with various embodiments, an anisotropic PVDF-based polymer thin film may be formed by applying a desired stress state to a crystallizable polymer thin film. A polymer composition capable of crystallizing may be formed into a single layer using appropriate casting operations. For example, a vinylidene fluoride-containing composition may be cast and oriented as a single layer to form a mechanically and piezoelectrically anisotropic thin film. According to further embodiments, a crystallizable polymer may be cast to form a thin film and plural such thin films may be laminated to form a multilayer structure.

In some embodiments, a polymer thin film having a bimodal molecular weight distribution may be stretched to a larger stretch ratio than a comparative polymer thin film (i.e., lacking a low molecular weight additive). In some examples, a stretch ratio may be greater than 4, e.g., 5, 10, 20, 40, or more. The act of stretching may include a single stretching step or plural (i.e., successive) stretching steps where one or more of a stretching temperature and a strain rate may be independently controlled.

In example methods, the polymer thin film may be heated during stretching to a temperature of from approximately 60° C. to approximately 170° C. and stretched at a strain rate of from approximately 0.1%/sec to approximately 300%/sec. Moreover, one or both of the temperature and the strain rate may be held constant or varied during an act of stretching. For instance, a polymer thin film may be stretched at a first temperature and a first strain rate (e.g., 130° C. and 50%/sec) to achieve a first stretch ratio. Subsequently, the temperature of the polymer thin film may be increased, and the strain rate may be decreased to a second temperature and a second strain rate (e.g., 165° C. and 5%/sec) to achieve a second stretch ratio.

Such a stretched polymer thin film may exhibit higher crystallinity and a higher elastic modulus. By way of example, an oriented polymer thin film having a bimodal molecular weight distribution may have an in-plane elastic modulus greater than approximately 2 GPa, e.g., 3, 5, 10, 12, or 15 GPa, including ranges between any of the foregoing values, and a piezoelectric coefficient (d₃₁) greater than approximately 5 pC/N, e.g., 7 pC/N, 10 pC/N, 12 pC/N, 15 pC/N, 17 pC/N, 20 pC/N, 22 pC/N, 25 pC/N, 27 pC/N, or 30 pC/N, including ranges between any of the foregoing values. High piezoelectric performance may be associated with the creation and alignment of beta phase crystals in PVDF-family polymers. As will be appreciated, the piezoelectric coefficient correlates the displacement of charge per unit area (i.e., volume change) with an applied stress (i.e., an applied electric field).

For piezoelectric polymers like PVDF homopolymer, the piezoelectric response may be tuned by altering the crystalline content and the crystalline orientation within the polymer matrix, e.g., by uniaxial or biaxial stretching, followed by poling. The origin of piezoelectricity in PVDF homopolymer is believed to be the β-phase crystallite polymorph, which is the most electrically active and polar of the PVDF phases. Alignment of the β-phase structure may be used to achieve the desired piezoelectric effect. Poling may be performed to align the β-phase and enhance the piezoelectric response. The piezoelectric response may be improved by poling with or without stretching.

Further to the foregoing, an electromechanical coupling factor kᵢⱼ may indicate the effectiveness with which a piezoelectric material may convert electrical energy into mechanical energy, or vice versa. For a polymer thin film, the electromechanical coupling factor k₃₁ may be expressed as

$${k}_{31} = \frac{d 31}{\sqrt{e 33 * s 11}} ,$$

where d₃₁ is the piezoelectric strain coefficient, e₃₃ is the dielectric permittivity in the thickness direction, and s₁₁ is the compliance in the machine direction. Higher values of k₃₁ may be achieved by disentangling polymer chains prior to stretching and promoting dipole moment alignment within a crystalline phase. In some embodiments, a polymer thin film may be characterized by an electromechanical coupling factor k₃₁ of at least approximately 0.1, e.g., 0.1, 0.2, 0.3, or more, including ranges between any of the foregoing values.

According to some embodiments, the crystalline content of an anisotropic polymer thin film may include crystals of poly(vinylidene fluoride), poly(trifluoroethylene), poly(chlorotrifluoroethylene), poly(hexafluoropropene), and/or poly(vinyl fluoride), for example, although further crystalline polymer materials are contemplated, where a crystalline phase in a “crystalline” or “semi-crystalline” polymer thin film may, in some examples, constitute at least approximately 1% of the polymer thin film. For instance, the crystalline content (e.g., beta phase content) of a polymer thin film may be at least approximately 1%, e.g., 1, 2, 4, 10, 20, 40, 60, or 80%, including ranges between any of the foregoing values.

Stretching a PVDF-family film may form both alpha and beta phase crystals, although only aligned beta phase crystals contribute to piezoelectric response. During and/or after a stretching process, an electric field may be applied to the polymer thin film. The application of an electric field (i.e., poling) may induce the formation and alignment of beta phase crystals within the film. Whereas a lower electric field (<50 V/micron) may be applied to align beta phase crystals, a higher electric field (≥50 V/micron) may be applied to both induce a phase transformation from the alpha phase to the beta phase and encourage alignment of the beta phase crystals.

In some embodiments, following stretching, the polymer thin film may be annealed. Annealing may be performed at a fixed or variable stretch ratio and/or a fixed or variable applied stress. An example annealing temperature may be greater than approximately 80° C., e.g., 100° C., 130° C., 150° C., 170° C., or 190° C., including ranges between any of the foregoing values. Without wishing to be bound by theory, annealing may stabilize the orientation of polymer chains and decrease the propensity for shrinkage of the polymer thin film.

Following deformation, the crystals or chains may be at least partially aligned with the direction of the applied tensile stress. As such, a polymer thin film may exhibit a high degree of birefringence, a high degree of optical clarity, bulk haze of less than approximately 10%, a high piezoelectric coefficient, e.g., d₃₁ greater than approximately 5 pC/N and/or a high electromechanical coupling factor, e.g., k₃₁ greater than approximately 0.1.

In example experiments, PVDF resin was dissolved completely in various liquid solvents, including DMF, cyclohexanone (CH), and mixtures of DMF and cyclohexanone. In one example, a 10 wt. % solution of PVDF in DMF was prepared under constant stirring at 60° C. (Sample 1). In a further example, a 10 wt. % solution of PVDF in cyclohexanone was prepared under constant stirring at 90° C. (Sample 4). A 50-50 w/w solvent mixture of DMF and cyclohexanone was used to prepare further 10 wt. % resin solutions under constant stirring at 80° C. (Samples 2 and 3).

The respective Samples 1-4 were maintained at the target temperature under constant stirring for 3 hr until the solution was clear. The solutions were then poured into separate vessels and allowed to form a gel over a period of approximately 1 hr. Following gelation, the gels were washed with methanol (5×) to remove residual solvent. The washed gels were stored in a fume hood overnight to evaporate the methanol and obtain a dry, white gel.

Successive calendering steps at room temperature were used to process the dried gels, where the roller gap was decreased with each successive pass through the calendering apparatus. Transparent thin films were obtained with stretch ratios ranging from approximately 2 to approximately 5.

The calendered polymer thin films were heated, stretched, and then measured for crystalline content. The act of stretching included locally heating the thin film samples to 140° C., initiating an applied stress, and increasing the temperature at a rate of 5° C./min to a target stretch temperature of approximately 160° C. until reaching an applied stress of 250 MPa, whereupon the thin film temperature was increased further at a rate of 1° C./min to 170° C. while maintaining the 250 MPa stress. The stretch ratio was between 10 and 12. Unannealed thin films were then cooled to less than 40° C. prior to removing the applied stress.

In some embodiments, a stretched thin film may be annealed. For example, after reaching a temperature of 170° C., the temperature may be increased further at a rate of 0.5° C./min to an annealing temperature of 195° C. under a constant applied stress of 250 MPa. The samples may be maintained at 195° C. for 40 min. The annealing process may increase the stretch ratio to values greater than 12, e.g., from 12 to 15. An annealed sample may be cooled to less than 40° C. prior to removing the applied stress.

After cooling, total crystallinity was measured using differential scanning calorimetry (DSC), and the relative beta phase ratio was determined using Fourier Transform Infrared Spectroscopy (FTIR). The absolute beta crystallinity was calculated as the product of the total crystallinity and the relative beta ratio. The modulus (i.e., storage modulus) was measured by dynamic mechanical analysis (DMA). The data in Table 1 indicate that a gel cast using a poor solvent (Sample 4) can achieve a higher modulus after stretching than a gel cast using a good solvent (Sample 1). In addition, annealing may increase both the total crystalline content and the modulus of a stretched thin film (Sample 2 and Sample 3).

TABLE 1
Effect of Solvent and Annealing on PVDF Thin Film Properties

| | | | | | Absolute | |
|---|---|---|---|---|---|---|
| | | | | Total | Beta | Modu- |
| Sam- | | | Relative | Crystal- | Crystal- | lus |
| ple | Solvent | Annealing? | Beta % | linity % | linity % | (GPa) |
| 1 | DMF | N | 97 | 61 | 59 | 5.1 |
| 2 | DMF:CH | N | 90 | 66 | 59 | 6.5 |
| 3 | DMF:CH | Y | 80 | 81 | 65 | 7.5 |
| 4 | CH | N | 96 | 69 | 66 | 10.3 |

In some examples, the applied stress during stretching may range from approximately 100 MPa to approximately 500 MPa, e.g., 100, 150, 200, 250, 300, 350, 400, 450, or 500 MPa, including ranges between any of the foregoing values. In a further example experiment where cyclohexane was used as a solvent, the thin film was stretched at a maximum applied stress of approximately 400 MPa.

In accordance with various embodiments, anisotropic polymer thin films may include fibrous, amorphous, partially crystalline, or wholly crystalline materials. Such materials may also be mechanically anisotropic, where one or more characteristics may include compressive strength, tensile strength, shear strength, yield strength, stiffness, hardness, toughness, ductility, machinability, thermal expansion, piezoelectric response, and creep behavior may be directionally dependent.

A polymer composition having a bimodal molecular weight may be formed into a single layer using casting operations. Alternatively, a polymer composition having a bimodal molecular weight may be cast with other polymers or other non-polymer materials to form a multilayer polymer thin film. The application of a uniaxial or biaxial stress to a cast single or multilayer thin film may be used to align polymer chains and/or re-orient crystals to induce mechanical and piezoelectric anisotropy therein.

A piezoelectric polymer thin film may be formed from a composition that includes a crystallizable polymer and a low molecular weight additive. In particular embodiments, a piezoelectric polymer thin film having a high electromechanical efficiency may be formed by a gel casting method. An example method may include forming a solution of a crystallizable polymer and a solvent, forming a gel from the solution by either decreasing the temperature of the solution, removing the solvent, adding a poor solvent, or a combination of thereof, and then calendering, orienting, and poling the thin film. The choice of solvent may facilitate chain disentanglement and accordingly polymer chain and dipole alignment, e.g., during orienting. The thin film may be characterized by an electromechanical coupling factor, k₃₁, of at least 0.1.

The crystallizable polymer and the low molecular weight additive may be independently selected to include vinylidene fluoride (VDF), trifluoroethylene (TrFE), chloride trifluoride ethylene (CTFE), hexafluoropropene (HFP), vinyl fluoride (VF), as well as homopolymers, co-polymers, tri-polymers, derivatives, and combinations thereof. The high molecular weight component of the polymer thin film may have a molecular weight of at least 100,000 g/mol, whereas the low molecular weight additive may have a molecular weight of less than 200,000 g/mol and may constitute 0.1 wt. % to 90 wt. % of the polymer thin film.

Aspects of the present disclosure thus relate to the formation of a single layer of a piezoelectrically anisotropic polymer thin film as well as a multilayer polymer thin film having improved mechanical and piezoelectric properties and including one or more piezoelectrically anisotropic polymer thin films. The application of a uniaxial or biaxial stress to a single or multilayer thin film may be used to align polymer chains and/or orient crystals to induce optical and mechanical anisotropy. Such thin films may be used to fabricate anisotropic piezoelectric substrates, birefringent substrates, high Poisson's ratio thin films, reflective polarizers, birefringent mirrors, and the like, and may be incorporated into AR/VR combiners or used to provide display brightness enhancement.

A piezoelectric membrane may be incorporated into a fluid pump and actuated, e.g., by the application of an electric field, to force fluid through the pump. As an example, a fluid pump may include a pump housing, a piezoelectric membrane mounted to the pump housing and defining a pump chamber within the pump housing, an inlet for feeding fluid into the pump chamber, an outlet for discharging fluid from the pump chamber, and a voltage source electrically coupled to the piezoelectric membrane for applying a voltage to the membrane and moving the membrane between a first position and a second position.

As disclosed herein, an example fluid pump includes a housing defining a fluid chamber and a piezoelectric membrane attached to the housing and located within the fluid chamber, where the piezoelectric membrane divides the fluid chamber into a first fluid cavity and a second fluid cavity. According to further embodiments, a fluid pump includes a housing having an opening, the housing defining a fluid chamber, and a piezoelectric membrane attached to the housing and extending over the opening.

A PVDF membrane-containing fluid pump may operate in resonant or static/non-resonance modes. Relative to ceramic piezoelectric materials, the displacement range of a pump may be extended by the incorporation of one or more PVDF polymer membranes. Furthermore, due to the lower elastic modulus of polymer membranes compared to ceramic membranes, the natural frequency and hence the frequency of operation of a resonant pump may be advantageously decreased. In certain examples, PVDF may have a different impedance than comparative ceramic materials, which for applications where the piezoelectric polymer pump operates in resonant modes, may allow for better impedance matching with the pump fluid.

For use in various systems, a fluid pump membrane including a PVDF-based polymer may be characterized by one or more of: (a) a thickness of between approximately 1 and 1000 microns, (b) a minimum areal dimension of greater than approximately 1 cm, and (c) a Young's modulus along at least one crystallographic axis of at least approximately 1 GPa, e.g., 1, 2, 4, 6, 8, 10, 20, 40, 60, or 80 GPa, including ranges between any of the foregoing values. Multilayer membranes may include mutually oriented or mis-oriented crystallographic axes, which may enable an isotropic or anisotropic net membrane stiffnesses.

Features from any of the embodiments described herein may be used in combination with one another in accordance with the general principles described herein. These and other embodiments, features, and advantages will be more fully understood upon reading the following detailed description in conjunction with the accompanying drawings and claims.

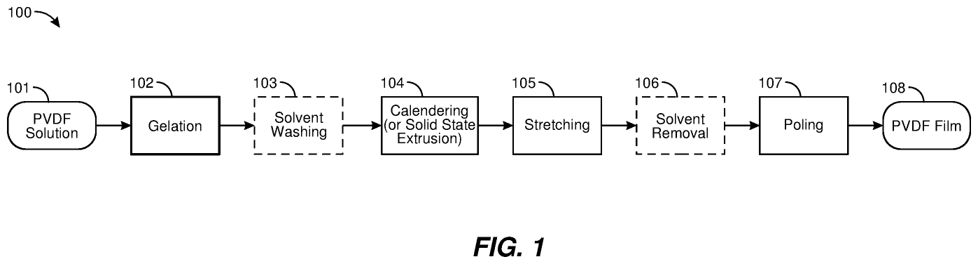

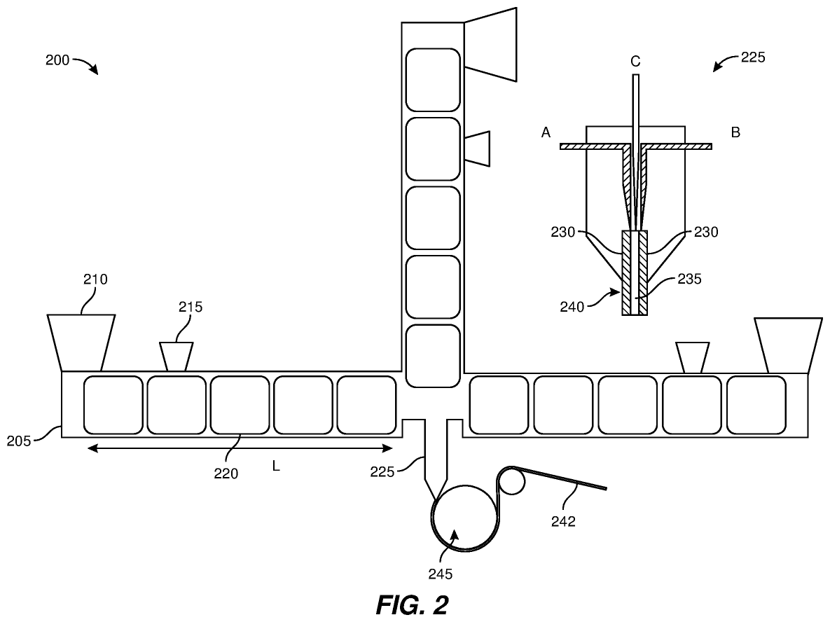

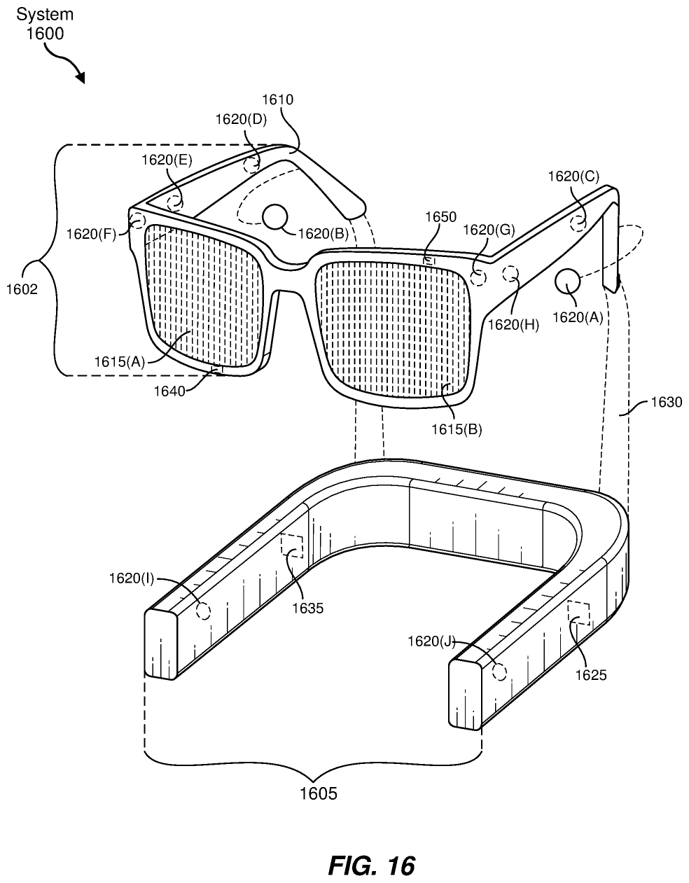

Further to the foregoing, the following will provide, with reference to FIGS. 1-21, a detailed description of methods, systems, and apparatuses for forming fluidic pumps having a piezoelectric polymer membrane. The discussion associated with FIG. 1 relates to an example gel casting method for forming a polymer thin film having high electromechanical efficiency. The discussion associated with FIGS. 2-7 relates to example polymer thin film forming and stretching paradigms and associated membrane architectures. The discussion associated with FIGS. 8-15 relates to the structure, operation, and performance of example fluid pumps that are configured to operate through the actuation and associated displacement of a piezoelectric polymer membrane. The discussion associated with FIGS. 16-21 relates to exemplary virtual reality, augmented reality, and fluidic devices that may include a piezoelectric membrane-based fluid pump as disclosed herein.

Referring to FIG. 1, shown is a flow chart depicting a gel casting method for forming a polymer thin film having a high electromechanical efficiency. An example method 100 may include forming a PVDF solution 101 by combining a crystallizable polymer and a solvent, forming a gel 102 from the PVDF solution by removing at least some of the solvent, decreasing the solution temperature, and/or adding a poor solvent, optionally washing the solvent 103, calendering the processed PVDF gel 104, stretching the gel 105 to form an oriented polymer thin film, optionally removing any remaining solvent 106 from the polymer thin film, and poling 107 the polymer thin film to form a PVDF polymer thin film having a high electromechanical efficiency 108. Solvent removal may include cooling the gel, adding to the gel a relatively poor solvent, or a combination thereof. Solvent removal may include a solvent washing step where the solvent is partially or wholly replaced with a secondary solvent that is then partially or completely removed. The acts of stretching, solvent removal, and poling may be performed in succession and/or in any concurrent processing paradigm.

Referring to FIG. 2, shown schematically is an example extrusion system for forming a cast polymer thin film. An extrusion system 200 may be configured to form a single layer polymer thin film or, as shown in the illustrated embodiment, a multilayer polymer thin film from plural sources. Different sources of feedstock may differ compositionally, for example. Multilayer polymer thin films may include 2 or more layers, where individual layers may be formed simultaneously in situ or aggregated to form a multilayer having, for example, 4, 8, 16, 32, 64, 128, 256, 512, or a greater number of individual layers.

During operation, a resin typically provided in powder or pellet form may be fed into extruder 205 from a hopper 210. One or more optional additives may be blended with the resin within hopper 210 or incorporated using a separate downstream hopper 215. The temperature of extruder 205 along its length (L) may be controlled by heating elements 220. Extruder 205 may include a screw or other element (not shown) for mixing, homogenizing, and driving feedstock from hoppers 210, 215 to an extrusion die 225.

As shown in the inset, extrusion die 225 may include plural inputs A, B, C, that are configured to receive feedstock from plural respective extruders (e.g., extruder 205, etc.). In some embodiments, the temperature of the die 225 may be greater than the melting point of the feedstock. The melted feedstock may be output through die 225 to form a multilayer thin film 240 that may include, for example, a central polymer layer 235 and a pair of outer layers 230 that sandwich the central layer 235. Multilayer thin film 240 may be initially collected on a chilled roller 245 and output as a pre-oriented cast thin film 242. The temperature of the chilled roller 245 may be selected based on the type of additive(s) used in the process. The rotational rate of the chilled roller 245 (i.e., relative to the output rate of the extrusion die 225) may be adjusted to pre-orient multilayer thin film 240.

In some embodiments, the central layer 235 may include PVDF. Each outer layer 230 may include a material having a high surface energy relative to PVDF or a material having a low surface energy relative to PVDF.

Prior to an act of stretching, one or both of the outer layers 230 may be removed from the multilayer thin film 240. By way of example, the outer layer(s) 230 may be removed prior to stretching the central layer 235, removed after one stage of stretching (e.g., removed after stretching along the machine direction), or removed following two stages of stretching (e.g., removed following an OCS process). In some embodiments, the outer layers 230 may be removed from the central layer 235 by peeling. In some embodiments, the outer layers 230 may have a 90° peel strength of at least approximately 10 g/cm width, e.g., 10, 20, 50, 100, 500, or 1000 g/cm width, including ranges between any of the foregoing values.

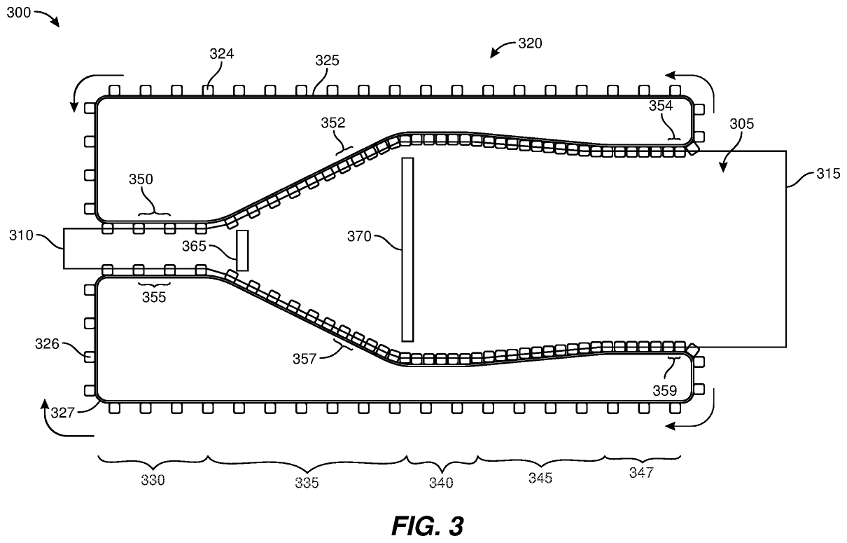

A single stage thin film orientation system for forming an optically anisotropic polymer thin film is shown schematically in FIG. 3. System 300 may include a thin film input zone 330 for receiving and pre-heating a crystallizable portion 310 of a polymer thin film 305, a thin film output zone 347 for outputting a crystallized and oriented portion 315 of the polymer thin film 305, and a clip array 320 extending between the input zone 330 and the output zone 347 that is configured to grip and guide the polymer thin film 305 through the system 300, i.e., from the input zone 330 to the output zone 347. Clip array 320 may include a plurality of movable first clips 324 that are slidably disposed on a first track 325 and a plurality of movable second clips 326 that are slidably disposed on a second track 327.

Polymer thin film 305 may include a single polymer layer or multiple (e.g., alternating) layers of first and second polymers, such as a multilayer ABAB . . . structure. Alternately, polymer thin film 305 may include a composite architecture having a crystallizable polymer thin film and a high Poisson's ratio polymer thin film directly overlying the crystallizable polymer thin film (not separately shown). In some embodiments, a polymer thin film composite may include a high Poisson's ratio polymer thin film reversibly laminated to, or printed on, a single crystallizable polymer thin film or a multilayer polymer thin film.

During operation, proximate to input zone 330, clips 324, 326 may be affixed to respective edge portions of polymer thin film 305, where adjacent clips located on a given track 325, 327 may be disposed at an inter-clip spacing 350, 355. For simplicity, in the illustrated view, the inter-clip spacing 350 along the first track 325 within input zone 330 may be equivalent or substantially equivalent to the inter-clip spacing 355 along the second track 327 within input zone 330. As will be appreciated, in alternate embodiments, within input zone 330, the inter-clip spacing 350 along the first track 325 may be different than the inter-clip spacing 355 along the second track 327.

In addition to input zone 330 and output zone 347, system 300 may include one or more additional zones 335, 340, 345, etc., where each of: (i) the translation rate of the polymer thin film 305, (ii) the shape of first and second tracks 325, 327, (iii) the spacing between first and second tracks 325, 327, (iv) the inter-clip spacing 350, 352, 354, 355, 357, 359, and (v) the local temperature of the polymer thin film 305, etc. may be independently controlled.

In an example process, as it is guided through system 300 by clips 324, 326, polymer thin film 305 may be heated to a selected temperature within each of zones 330, 335, 340, 345, 347. Fewer or a greater number of thermally controlled zones may be used. As illustrated, within zone 335, first and second tracks 325, 327 may diverge along a transverse direction such that polymer thin film 305 may be stretched in the transverse direction while being heated, for example, to a temperature greater than its glass transition temperature (T_{g}) but less than the onset of melting.

Referring still to FIG. 3, within zone 335 the spacing 352 between adjacent first clips 324 on first track 325 and the spacing 357 between adjacent second clips 326 on second track 327 may decrease relative to the inter-clip spacing 350, 355 within input zone 330. In certain embodiments, the decrease in clip spacing 352, 357 from the initial spacing 350, 355 may scale approximately as the square root of the transverse stretch ratio. The actual ratio may depend on the Poisson's ratio of the polymer thin film as well as the requirements for the stretched thin film, including flatness, thickness, etc. Accordingly, in some embodiments, the in-plane axis of the polymer thin films that is perpendicular to the stretch direction may relax by an amount equal to the square root of the stretch ratio in the stretch direction. By decreasing the clip spacings 352, 357 relative to inter-clip spacing 350, 355 the polymer thin film may be allowed to relax along the machine direction while being stretched along the transverse direction.

A temperature of the polymer thin film may be controlled within each heating zone. Withing stretching zone 335, for example, a temperature of the polymer thin film 305 may be constant or independently controlled within sub-zones 365, 370, for example. In some embodiments, the temperature of the polymer thin film 305 may be decreased as the stretched polymer thin film 305 enters zone 340. Rapidly decreasing the temperature (i.e., thermal quenching) following the act of stretching within zone 335 may enhance the conformability of the polymer thin film 305. In some embodiments, the polymer thin film 305 may be thermally stabilized, where the temperature of the polymer thin film 305 may be controlled within each of the post-stretch zones 340, 345, 347. A temperature of the polymer thin film may be controlled by forced thermal convection or by radiation, for example, IR radiation, or a combination thereof.

Downstream of stretching zone 335, according to some embodiments, a transverse distance between first track 325 and second track 327 may remain constant or, as illustrated, initially decrease (e.g., within zone 340 and zone 345) prior to assuming a constant separation distance (e.g., within output zone 347). In a related vein, the inter-clip spacing downstream of stretching zone 335 may increase or decrease relative to inter-clip spacing 352 along first track 325 and inter-clip spacing 357 along second track 327. For example, inter-clip spacing 355 along first track 325 within output zone 347 may be less than inter-clip spacing 352 within stretching zone 335, and inter-clip spacing 359 along second track 327 within output zone 347 may be less than inter-clip spacing 357 within stretching zone 335. According to some embodiments, the spacing between the clips may be controlled by modifying the local velocity of the clips on a linear stepper motor line, or by using an attachment and variable clip spacing mechanism connecting the clips to the corresponding track.

To facilitate cross-stretch relaxation while stretching in the TD direction, the inter-clip spacings 352, 357 withing stretching zone 335 may be decreased by at least approximately 20% (e.g., 20%, 30%, 40%, or 50% or more) relative to respective inter-clip spacings 350, 355 within input zone 330. The relaxation profile may be constant or variable, i.e., as a function of position, across stretching zone 335. According to some embodiments, a maximum TD draw ratio within stretching zone 335 be at least approximately 2 and less than approximately 4. The stretched and oriented polymer thin film 315 may be removed from system 300 and stretched in a further stretching step, such as via length orientation with relaxation.

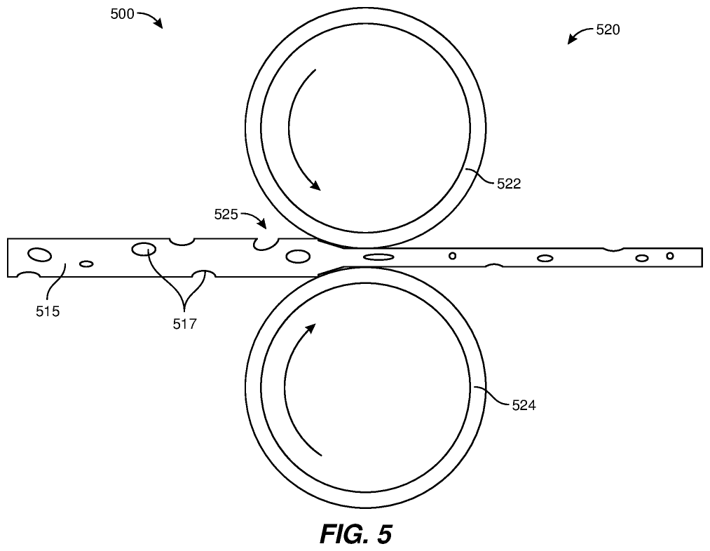

In some embodiments, a roll-to-roll system may be integrated with a thin film orientation system, such as thin film orientation system 300, to manipulate a polymer thin film. In further embodiments, as illustrated herein with reference FIG. 5, a roll-to-roll system may itself be configured as a thin film orientation system.

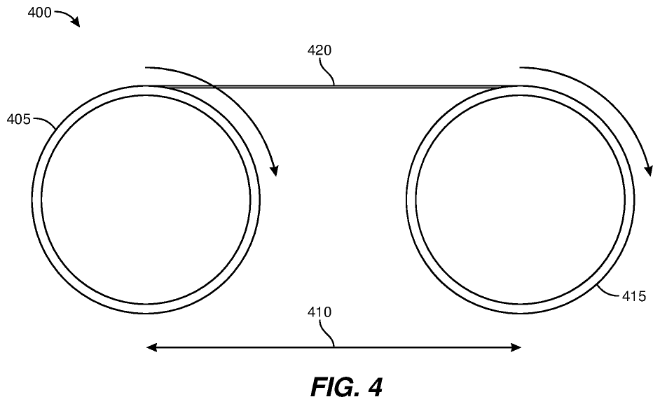

An example roll-to-roll polymer thin film orientation system is depicted in FIG. 4. In conjunction with system 400, a method for stretching a polymer thin film 420 may include mounting the polymer thin film between linear rollers 405, 415 and heating a portion of the polymer thin film located between the rollers 405, 415 to a temperature greater than its glass transition temperature. Rollers 405, 415 may be arranged with a controllable spacing 410 therebetween. A heat source (not shown), such as an IR source optionally equipped with an IR reflector, may be used to heat the polymer thin film 420 within a deformation region between the rollers.

While controlling the temperature of the polymer thin film, rollers 405, 415 may be engaged and the polymer thin film may be stretched. For instance, first roller 405 may rotate at a first rate and second roller 415 may rotate at a second rate greater than the first rate to stretch the polymer thin film along a machine direction therebetween. Within a deformation zone between rollers, system 400 may be configured to locally control the temperature and the strain rate of the polymer thin film. In some examples, as the polymer thin film advances from roller 405 to roller 415, a temperature of the polymer thin film may increase, and a strain rate of the polymer thin film may decrease. Downstream of roller 415, the polymer thin film may then be cooled while maintaining the applied stress. System 400 may be used to form a uniaxially oriented polymer thin film. Additional rollers may be added to system 400 to control the conveyance and take-up of the polymer thin film.

Referring to FIG. 5, shown schematically is a calendering method for manufacturing an anisotropic polymer thin film. In method 500, a stretched PVDF thin film 515, such as oriented polymer thin film 315, may be fed into a calendering system 520. Calendering system 520 may include a pair of counter-rotating rollers 522, 524 defining a nip region 525. As the thin film 515 passes into the nip region 525 and between the rollers 522, 524, the thin film 515 may be compressed. In exemplary embodiments, rollers 522, 524 may be heated. In some examples, the temperature of the rollers during calendering may be greater than the glass transition temperature of the polymer. In some examples, the temperature of the rollers during calendering may be less than, equal to, or greater than the melting onset temperature of the polymer.

During calendering, voids 517 present in stretched PVDF thin film 515 may be compressed, and the overall void fraction within the thin film may be decreased. Moreover, voids exposed at a surface of the thin film may be smoothed, resulting in decreased surface roughness and, together with compression of voids within the bulk of the thin film, higher transmissivity and higher thermal conductivity.

According to some embodiments, a polymer thin film may include a crystalline polymer and a low (i.e., lower) molecular weight additive. The piezoelectric performance of PVDF and other PVDF-family polymer thin films, for instance, may be determined by the amount of oriented beta phase crystals in the film. Beta phase crystals may be formed during the acts of film forming, stretching, and/or electric poling.

Whereas the total crystallinity and the degree of crystalline alignment may be limited by conventional processing, e.g., due to chain entanglement, Applicants have shown that a gel casting method, optionally in conjunction with the addition of a low molecular weight additive to a thin film composition, may decrease chain entanglement of the high molecular weight component, which may increase the overall extent of beta phase crystallization as well as increase the alignment of beta phase crystals within the polymer thin film, e.g., during forming, stretching and/or poling operations.

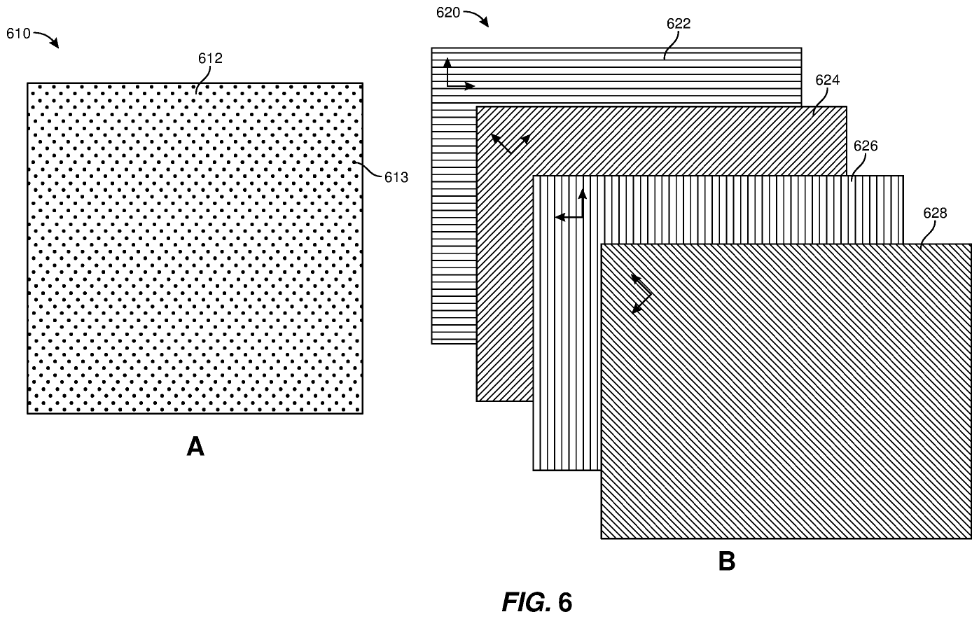

Referring to FIG. 6A, shown is an example PVDF-based membrane 610. Membrane 610 may include a polymer matrix 612 and a particular or fibrous additive 613 dispersed throughout the matrix 612. Additive 613 may include an inorganic additive.

Referring to FIG. 6B, example multilayer membrane 620 includes first, second, third, and fourth polymer layers 622, 624, 626, 628. Each polymer layer may be a drawn and poled layer and, as illustrated schematically, may be mutually misoriented by a suitable in-plane angle, e.g., approximately 45°. With such a configuration, one or more in-plane properties, such as the piezoelectric coefficient, may be arranged to provide a net in-plane piezoelectric response effective to exert a force along a desired direction during actuation of the membrane 620. Although the instant embodiment is shown with four layers arranged at a mutual misorientation of 45°, it will be appreciated that fewer or a greater number of polymer layers may be used, and that the angular misorientation may be constant or variable and may be less than or greater than 45°, e.g., 2, 5, 10, 15, 20, 30, 40, 50, 60, 70, 80, or 90°, including ranges between any of the foregoing values. In the illustrated example of FIG. 6B, adhesive layer(s) are omitted so as to not obscure the illustrated embodiment.

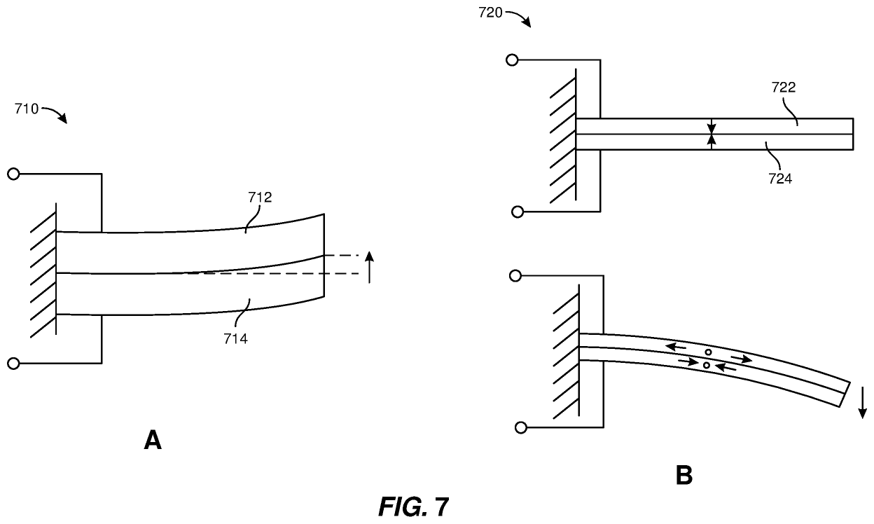

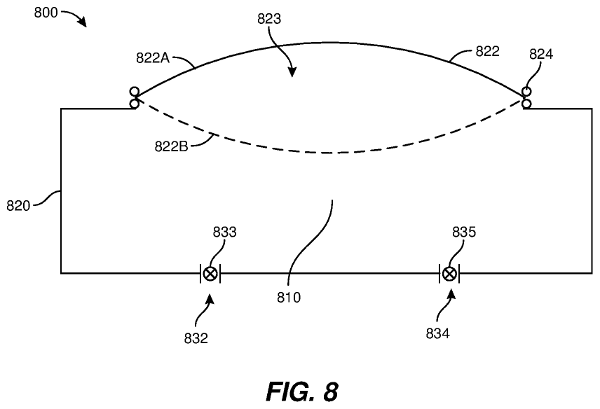

Piezoelectric polymer membranes configured as unimorph and bimorph actuators are shown in FIG. 7. Referring to FIG. 7A, unimorph actuator 710 may include an active (e.g., piezoelectric) layer 712 and a passive (e.g., elastic) layer 714. Referring to FIG. 7B, a serial bimorph actuator 720 may include a pair of active (e.g., piezoelectric) layers 722, 724. In alternate embodiments, bimorph actuator 720 may additionally include a passive layer (not shown) sandwiched between active layers 722, 724, or disposed over one or both of the active layers.

Referring to FIG. 8, illustrated is a schematic cross-sectional view of an exemplary fluid pump including a piezoelectric polymer membrane. Fluid pump 800 includes a chamber 810 defined by a rigid housing 820 and a piezoelectric polymer membrane 822 extending across an opening 823 in the housing 820. Membrane 822 may be integrated with housing 820 via O-rings 824, for example, although alternate attachment approaches may be used. The illustrated fluid pump 800 additionally includes an inlet port 832 and an outlet port 834, each fitted with a respective valve 833, 835 (e.g., 1-way valves). During operation, actuation of the membrane 822 to a first position 822A may increase the chamber volume to draw fluid into the chamber 810 through the inlet port 832. Actuation of the membrane 822 to a second position 822B may decrease the chamber volume and force fluid out of the chamber 810 through the outlet port 834.

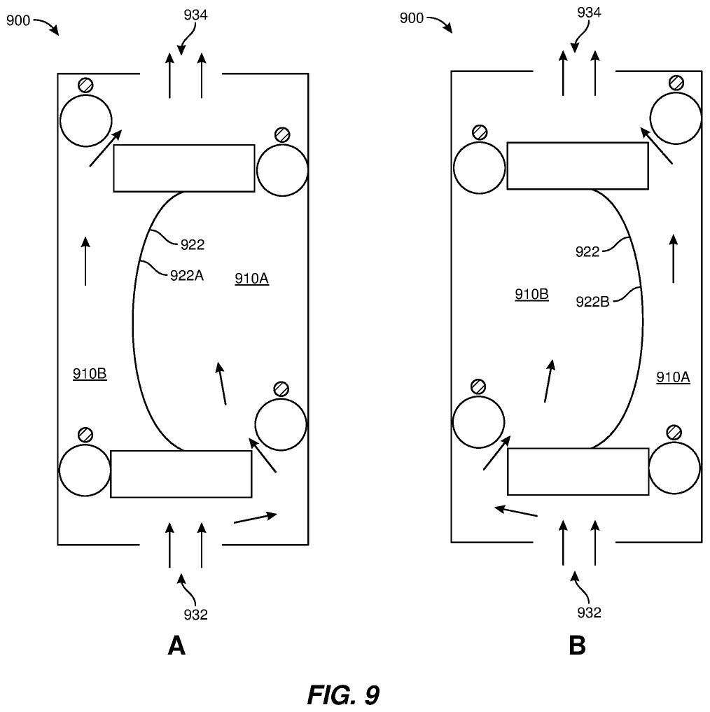

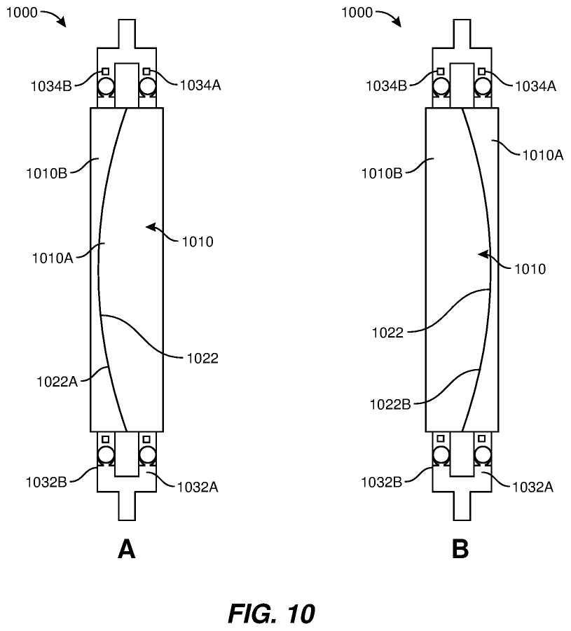

Referring to FIG. 9, a dual chamber fluid pump 900 may include a piezoelectric polymer membrane 922 located between the chambers. In a first configuration, as shown in FIG. 9A, the membrane 922 may be actuated to a first position 922A to draw fluid from the inlet 932 into the right-hand chamber 910A while expelling fluid through the outlet 934 from the left-hand chamber 910B. In a second configuration, as shown in FIG. 9B, the membrane 922 may be actuated to a second position 922B to draw fluid from the inlet 932 into the left-hand chamber 910B while expelling fluid through the outlet 934 from the right-hand chamber 910A. An alternating cycle of first and second configurations may be used to continuously or semi-continuously pump fluid through the pump 900. Arrows show the direction of fluid flow. An analogous pump having dual inlets and dual outlets is shown in FIG. 10.

Referring to FIG. 10, fluid pump 1000 includes a pair of inlet valves 1032A, 1032B and a pair of outlet valves 1034A, 1034B arranged at opposite sides of pump cavity 1010. A piezoelectric membrane 1022 divides pump cavity 1010 into a right-hand chamber 1010A and a left-hand chamber 1010B. In the illustrated embodiment, right-hand chamber 1010A is in fluid communication with inlet valve 1032A and outlet valve 1034A, and left-hand chamber 1010B is in fluid communication with inlet valve 1032B and outlet valve 1034B. During operation, actuation of the membrane 1022 alternately between a first configuration 1022A (as shown in FIG. 10A) and a second configuration 1022B (as shown in FIG. 10B) may be used to alternately fill and empty the adjacent chambers 1010A, 1010B.

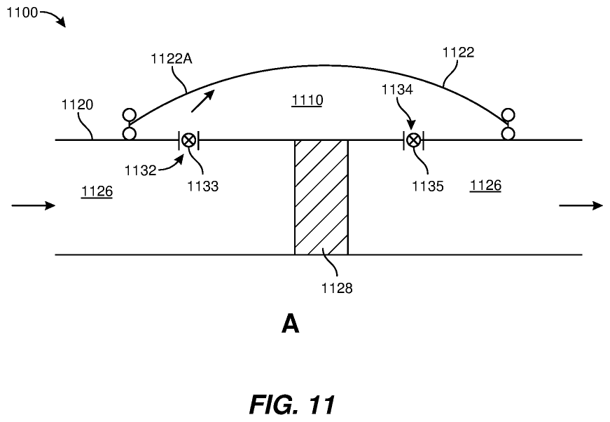

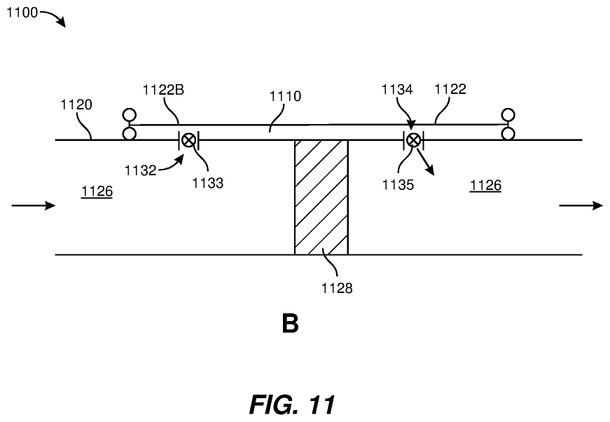

A further example fluid pump is illustrated schematically in FIG. 11. In fluid pump 1100, a chamber 1110 is defined by a housing 1120 and a piezoelectric polymer membrane 1122 attached to the housing 1120. During operation, with reference initially to FIG. 11A, actuation of the membrane 1122 to a first position 1122A may increase the chamber volume to draw fluid into the chamber 1110 from a fluid channel 1126 through an inlet 1132 upstream of channel barrier 1128. Referring to FIG. 11B, actuation of the membrane 1122 to a second position 1122B may decrease the chamber volume and force fluid out of the chamber 1110 through an outlet 1134 into fluid channel 1126 downstream of channel barrier 1128. The overall direction of fluid flow through fluid pump 1100 is annotated with block arrows. In various embodiments, inlet 1132 and outlet 1134 of fluid pump 1100 may include a 1-way valve 1133, 1135, respectively.

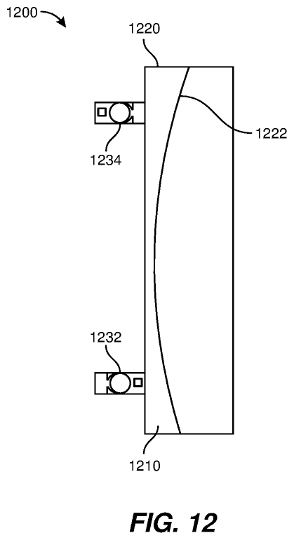

Turning to FIG. 12, illustrated is a fluid pump having single-chamber operation. Pump 1200 includes an inlet port 1232 and an outlet port 1234 each in fluid communication with a chamber 1210. Chamber 1210 may be defined by a housing 1220 and a piezoelectric polymer membrane 1222 attached to the housing 1220. In some embodiments, the inlet port 1232 and the outlet port 1234 each may be fitted with a 1-way valve. Actuation of the piezoelectric polymer membrane 1222 may alternately draw fluid into and expel fluid from the chamber 1210 via the inlet port 1232 and the outlet port 1234.

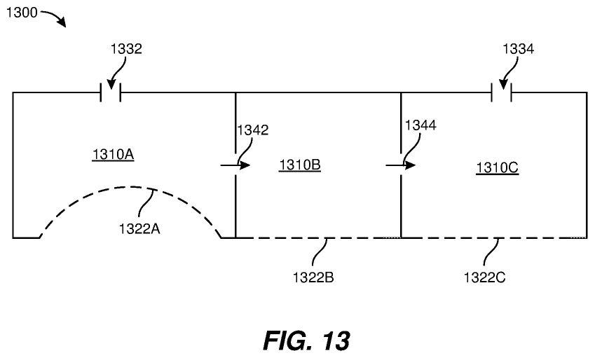

Referring to FIG. 13, a further example fluid pump 1300 may include a plurality of pump chambers 1310A, 1310B, 1310C arranged in series and a corresponding plurality of piezoelectric polymer membranes 1322A, 1322B, 1322C each configured to apply pressure to fluid located within a respective chamber. In some embodiments, coordinated actuation of the plural membranes 1322A, 1322B, 1322C may be used to progressively move fluid amongst the chambers, i.e., from inlet port 1332 to outlet port 1334 via the inlet chamber 1310A, the middle chamber 1310B, and the outlet chamber 1310C. As shown in the illustrated embodiment, valves 1342 and 1344 (e.g., 1-way valves) may be configured to mediate the fluid flow between the chambers.

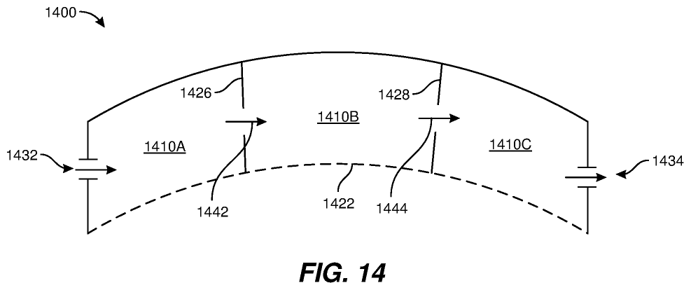

In further embodiments, and with reference to FIG. 14, a fluid pump 1400 may include plural chambers (e.g., inlet chamber 1410A, middle chamber 14106, and outlet chamber 1410C) and a single piezoelectric polymer membrane 1422 configured to apply pressure independently or in combination to fluid located within the chamber(s). Such a membrane 1422 may be locally actuated in a prescribed manner to direct fluid from the inlet port 1432 to the outlet port 1434 of pump 1400. As illustrated, fluid pump 1400 may include inter-chamber partitions 1426, 1428 and corresponding valves 1442, 1444 (e.g., 1-way valves).

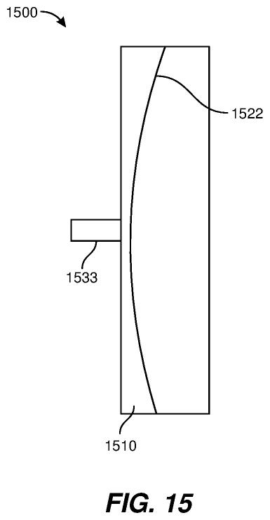

Referring to FIG. 15, a further example fluid pump includes a common inlet/outlet. Pump 1500 may include an inlet/outlet 1533 in fluid communication with a chamber 1510. Actuation of piezoelectric polymer membrane 1522 may draw fluid into and subsequently expel fluid from the chamber 1510 via dual inlet/outlet 1533. Pump 1500 may be used to generate a puff of air, for example.

The present disclosure relates to microfluidic pump systems and associated methods that may involve one or more pump chambers for pressurizing and/or flowing a fluid. In connection with various embodiments, the microfluidic pump systems may include a check valve at an outlet of the pump for inhibiting backflow of the fluid. Some of the pumps may include or lack an exhaust port to ambient. In further examples, two or more pump subsystems may, in series and/or parallel, be used to pressurize and/or flow fluid with greater capabilities (e.g., in flow rate and/or in pressure) compared to microfluidic pump systems with only one pump subsystem. In some examples, embodiments of the present disclosure may exhibit improved operational efficiency compared to comparative microfluidic pump systems.

In accordance with various embodiments, a fluid pump includes a piezoelectric membrane that is configured to provide a pumping force as a response to the application of an electric field to the membrane. In some embodiments, the membrane may exhibit a bi-stable configuration, e.g., between two actuated states. Suitable membrane materials may include ionically conductive polymers and electrostrictive polymers and ceramics.

According to particular embodiments, the piezoelectric membrane may include polyvinylidene fluoride (PVDF), which may, in some embodiments, be at least partially crystalline. In certain embodiments, the piezoelectric material may be poled prior to use to improve its electrical response. For instance, conductive electrodes (e.g., metal, glass, etc.) may be applied to a PVDF membrane to transmit an electric field to the material for poling. In further examples, a corona poling process may be used.

According to particular embodiments, the piezoelectric membrane may include polyvinylidene fluoride (PVDF), which may, in some embodiments, be at least partially crystalline. In certain embodiments, the piezoelectric material may be poled prior to use to improve its electrical response. For instance, conductive electrodes may be applied to a PVDF membrane to transmit an electric field to the material for poling. Example electrodes may include a metal such as thin film coatings of silver, copper, or gold, transparent conductive oxides such as indium tin oxide (ITO) or indium gallium zinc oxide (IGZO), or composites such as nanowires, including silver nanowires, single and multiwall carbon nanotubes, graphene, or combinations and composites thereof. In further examples, a corona poling process may be used, and one or more electrodes for actuation may be applied after poling.

An electrode may be applied as a uniform coating, or may be applied as a structure such as a grid or having a helical form. The electroactive surface may be primed before coating with an electrode. For example, PVDF may be primed with a plasma or corona treatment, such as an oxygen- or nitrogen-based process. In some examples, an electrode may be coated over the primed surface, and optionally coated with a protective coating such as an acrylate, silicone, polyurethane, as well as combinations thereof. A protective coating may have a thickness of between approximately 0.1 and 10 microns. In some applications, the electroactive layer (i.e., piezoelectric polymer) may have a floating voltage reference to ground, or one of the electrodes may be grounded.

In certain embodiments, the piezoelectric membrane may be reversibly actuatable, e.g., by alternating the sign of an applied electric field during operation of the pump. In some embodiments, the pumping force may be oscillated to drive fluid through the pump. An example fluid pump may include a pump housing, a piezoelectric membrane affixedly or slidably mounted to the pump housing to define a pump chamber within the pump housing, an inlet for feeding fluid into the pump chamber, an outlet for discharging fluid from the pump chamber, and a voltage source electrically coupled to the piezoelectric membrane for applying a voltage to the membrane and moving the membrane between a first position and a second position.

A fluid pump including a piezoelectric membrane may be configured as a diaphragm pump or a traveling wave pump, for example. Relative to comparative membrane materials, including electrostrictive polymers and ceramics, a PVDF polymer may be light weight, mechanically durable, chemically inert, optically transparent, free of lead and other heavy metal constituents, actuated to higher strains/displacements, thermally compatible with other pump components, and economical to manufacture.

### EXAMPLE EMBODIMENTS

Example 1: A fluid pump includes a housing defining a fluid chamber and a piezoelectric membrane attached to the housing and located within the fluid chamber, where the piezoelectric membrane divides the fluid chamber into a first fluid cavity and a second fluid cavity.

Example 2: The fluid pump of Example 1, where the piezoelectric membrane includes polyvinylidene fluoride (PVDF).

Example 3: The fluid pump of any of Examples 1 and 2, where the piezoelectric membrane includes a particulate or fibrous piezoelectric ceramic.

Example 4: The fluid pump of any of Examples 1-3, where the piezoelectric membrane has an in-plane elastic modulus of at least approximately 1 GPa.

Example 5: The fluid pump of any of Examples 1-4, where the piezoelectric membrane is movable between a first position and a second position relative to the housing.

Example 6: The fluid pump of any of Examples 1-5, where the piezoelectric membrane is configured to oscillate relative to the housing.

Example 7: The fluid pump of any of Examples 1-6, further including an inlet port for adding fluid to the fluid chamber and an outlet port for removing fluid from the fluid chamber.

Example 8: The fluid pump of any of Examples 1-7, where the inlet port and the outlet port each include a one-way valve.

Example 9: The fluid pump of any of Examples 1-8, where the piezoelectric membrane is configured as a unimorph actuator.

Example 10: The fluid pump of any of Examples 1-8, where the piezoelectric membrane is configured as a bimorph actuator.

Example 11: The fluid pump of any of Examples 1-10, where the piezoelectric membrane is bi-stable.

Example 12: A fluid pump includes a housing having an opening, the housing defining a fluid chamber, and a piezoelectric membrane attached to the housing and extending over the opening.

Example 13: The fluid pump of Example 12, where the piezoelectric membrane includes polyvinylidene fluoride (PVDF).

Example 14: The fluid pump of any of Examples 12 and 13, further including an inlet port for adding fluid to the fluid chamber and an outlet port for removing fluid from the fluid chamber.

Example 15: The fluid pump of any of Examples 12-14, where the inlet port and the outlet port each include a one-way valve.

Example 16: The fluid pump of any of Examples 12-15, where the piezoelectric membrane is bi-stable.

Example 17: A method includes applying an electric field to a piezoelectric membrane to oscillate the piezoelectric membrane, where the oscillating piezoelectric membrane applies a force to a fluid in an amount effective to displace the fluid.

Example 18: The method of Example 17, where the piezoelectric membrane oscillates at a resonant frequency.

Example 19: The method of any of Examples 17 and 18, where the piezoelectric membrane directly contacts the fluid.

Example 20: The method of any of Examples 17-19, where the piezoelectric membrane includes polyvinylidene fluoride (PVDF).

Embodiments of the present disclosure may include or be implemented in conjunction with various types of artificial-reality systems. Artificial reality is a form of reality that has been adjusted in some manner before presentation to a user, which may include, for example, a virtual reality, an augmented reality, a mixed reality, a hybrid reality, or some combination and/or derivative thereof. Artificial-reality content may include completely computer-generated content or computer-generated content combined with captured (e.g., real-world) content. The artificial-reality content may include video, audio, haptic feedback, or some combination thereof, any of which may be presented in a single channel or in multiple channels (such as stereo video that produces a three-dimensional (3D) effect to the viewer). Additionally, in some embodiments, artificial reality may also be associated with applications, products, accessories, services, or some combination thereof, that are used to, for example, create content in an artificial reality and/or are otherwise used in (e.g., to perform activities in) an artificial reality.

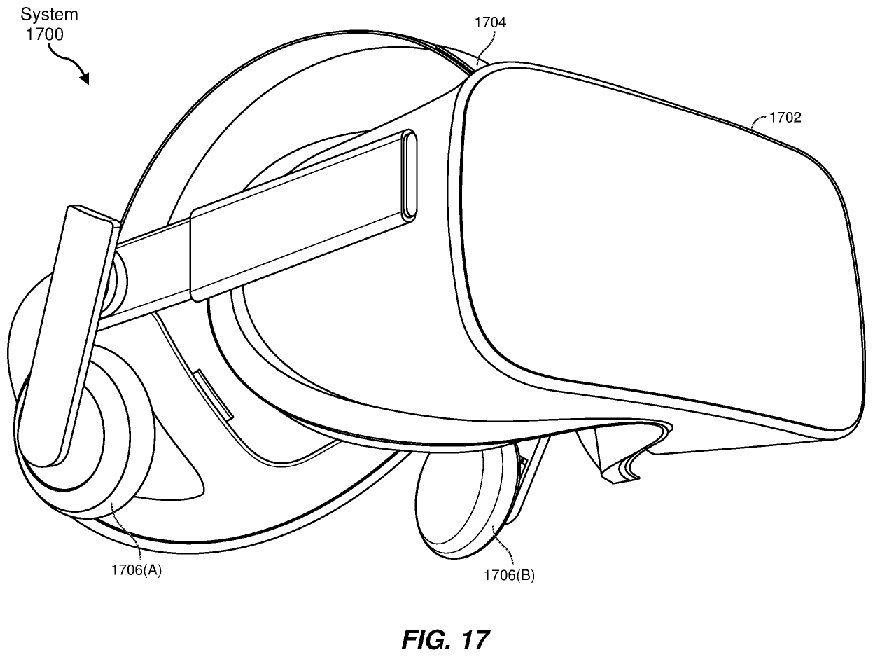

Artificial-reality systems may be implemented in a variety of different form factors and configurations. Some artificial-reality systems may be designed to work without near-eye displays (NEDs). Other artificial-reality systems may include an NED that also provides visibility into the real world (such as, e.g., augmented-reality system 1600 in FIG. 16) or that visually immerses a user in an artificial reality (such as, e.g., virtual-reality system 1700 in FIG. 17). While some artificial-reality devices may be self-contained systems, other artificial-reality devices may communicate and/or coordinate with external devices to provide an artificial-reality experience to a user. Examples of such external devices include handheld controllers, mobile devices, desktop computers, devices worn by a user, devices worn by one or more other users, and/or any other suitable external system.

Turning to FIG. 16, augmented-reality system 1600 may include an eyewear device 1602 with a frame 1610 configured to hold a left display device 1615(A) and a right display device 1615(B) in front of a user's eyes. Display devices 1615(A) and 1615(B) may act together or independently to present an image or series of images to a user. While augmented-reality system 1600 includes two displays, embodiments of this disclosure may be implemented in augmented-reality systems with a single NED or more than two NEDs.

In some embodiments, augmented-reality system 1600 may include one or more sensors, such as sensor 1640. Sensor 1640 may generate measurement signals in response to motion of augmented-reality system 1600 and may be located on substantially any portion of frame 1610. Sensor 1640 may represent one or more of a variety of different sensing mechanisms, such as a position sensor, an inertial measurement unit (IMU), a depth camera assembly, a structured light emitter and/or detector, or any combination thereof. In some embodiments, augmented-reality system 1600 may or may not include sensor 1640 or may include more than one sensor. In embodiments in which sensor 1640 includes an IMU, the IMU may generate calibration data based on measurement signals from sensor 1640. Examples of sensor 1640 may include, without limitation, accelerometers, gyroscopes, magnetometers, other suitable types of sensors that detect motion, sensors used for error correction of the IMU, or some combination thereof.

In some examples, augmented-reality system 1600 may also include a microphone array with a plurality of acoustic transducers 1620(A)-1620(J), referred to collectively as acoustic transducers 1620. Acoustic transducers 1620 may represent transducers that detect air pressure variations induced by sound waves. Each acoustic transducer 1620 may be configured to detect sound and convert the detected sound into an electronic format (e.g., an analog or digital format). The microphone array in FIG. 16 may include, for example, ten acoustic transducers: 1620(A) and 1620(B), which may be designed to be placed inside a corresponding ear of the user, acoustic transducers 1620(C), 1620(D), 1620(E), 1620(F), 1620(G), and 1620(H), which may be positioned at various locations on frame 1610, and/or acoustic transducers 1620(I) and 1620(J), which may be positioned on a corresponding neckband 1605.

In some embodiments, one or more of acoustic transducers 1620(A)-(J) may be used as output transducers (e.g., speakers). For example, acoustic transducers 1620(A) and/or 1620(B) may be earbuds or any other suitable type of headphone or speaker.

The configuration of acoustic transducers 1620 of the microphone array may vary. While augmented-reality system 1600 is shown in FIG. 16 as having ten acoustic transducers 1620, the number of acoustic transducers 1620 may be greater or less than ten. In some embodiments, using higher numbers of acoustic transducers 1620 may increase the amount of audio information collected and/or the sensitivity and accuracy of the audio information. In contrast, using a lower number of acoustic transducers 1620 may decrease the computing power required by an associated controller 1650 to process the collected audio information. In addition, the position of each acoustic transducer 1620 of the microphone array may vary. For example, the position of an acoustic transducer 1620 may include a defined position on the user, a defined coordinate on frame 1610, an orientation associated with each acoustic transducer 1620, or some combination thereof.

Acoustic transducers 1620(A) and 1620(B) may be positioned on different parts of the user's ear, such as behind the pinna, behind the tragus, and/or within the auricle or fossa. Or, there may be additional acoustic transducers 1620 on or surrounding the ear in addition to acoustic transducers 1620 inside the ear canal. Having an acoustic transducer 1620 positioned next to an ear canal of a user may enable the microphone array to collect information on how sounds arrive at the ear canal. By positioning at least two of acoustic transducers 1620 on either side of a user's head (e.g., as binaural microphones), augmented-reality device 1600 may simulate binaural hearing and capture a 3D stereo sound field around about a user's head. In some embodiments, acoustic transducers 1620(A) and 1620(B) may be connected to augmented-reality system 1600 via a wired connection 1630, and in other embodiments acoustic transducers 1620(A) and 1620(B) may be connected to augmented-reality system 1600 via a wireless connection (e.g., a BLUETOOTH connection). In still other embodiments, acoustic transducers 1620(A) and 1620(B) may not be used at all in conjunction with augmented-reality system 1600.

Acoustic transducers 1620 on frame 1610 may be positioned in a variety of different ways, including along the length of the temples, across the bridge, above or below display devices 1615(A) and 1615(B), or some combination thereof. Acoustic transducers 1620 may also be oriented such that the microphone array is able to detect sounds in a wide range of directions surrounding the user wearing the augmented-reality system 1600. In some embodiments, an optimization process may be performed during manufacturing of augmented-reality system 1600 to determine relative positioning of each acoustic transducer 1620 in the microphone array.

In some examples, augmented-reality system 1600 may include or be connected to an external device (e.g., a paired device), such as neckband 1605. Neckband 1605 generally represents any type or form of paired device. Thus, the following discussion of neckband 1605 may also apply to various other paired devices, such as charging cases, smart watches, smart phones, wrist bands, other wearable devices, hand-held controllers, tablet computers, laptop computers, other external compute devices, etc.

As shown, neckband 1605 may be coupled to eyewear device 1602 via one or more connectors. The connectors may be wired or wireless and may include electrical and/or non-electrical (e.g., structural) components. In some cases, eyewear device 1602 and neckband 1605 may operate independently without any wired or wireless connection between them. While FIG. 16 illustrates the components of eyewear device 1602 and neckband 1605 in example locations on eyewear device 1602 and neckband 1605, the components may be located elsewhere and/or distributed differently on eyewear device 1602 and/or neckband 1605. In some embodiments, the components of eyewear device 1602 and neckband 1605 may be located on one or more additional peripheral devices paired with eyewear device 1602, neckband 1605, or some combination thereof.

Pairing external devices, such as neckband 1605, with augmented-reality eyewear devices may enable the eyewear devices to achieve the form factor of a pair of glasses while still providing sufficient battery and computation power for expanded capabilities. Some or all of the battery power, computational resources, and/or additional features of augmented-reality system 1600 may be provided by a paired device or shared between a paired device and an eyewear device, thus reducing the weight, heat profile, and form factor of the eyewear device overall while still retaining desired functionality. For example, neckband 1605 may allow components that would otherwise be included on an eyewear device to be included in neckband 1605 since users may tolerate a heavier weight load on their shoulders than they would tolerate on their heads. Neckband 1605 may also have a larger surface area over which to diffuse and disperse heat to the ambient environment. Thus, neckband 1605 may allow for greater battery and computation capacity than might otherwise have been possible on a stand-alone eyewear device. Since weight carried in neckband 1605 may be less invasive to a user than weight carried in eyewear device 1602, a user may tolerate wearing a lighter eyewear device and carrying or wearing the paired device for greater lengths of time than a user would tolerate wearing a heavy standalone eyewear device, thereby enabling users to more fully incorporate artificial-reality environments into their day-to-day activities.

Neckband 1605 may be communicatively coupled with eyewear device 1602 and/or to other devices. These other devices may provide certain functions (e.g., tracking, localizing, depth mapping, processing, storage, etc.) to augmented-reality system 1600. In the embodiment of FIG. 16, neckband 1605 may include two acoustic transducers (e.g., 1620(I) and 1620(J)) that are part of the microphone array (or potentially form their own microphone subarray). Neckband 1605 may also include a controller 1625 and a power source 1635.

Acoustic transducers 1620(I) and 1620(J) of neckband 1605 may be configured to detect sound and convert the detected sound into an electronic format (analog or digital). In the embodiment of FIG. 16, acoustic transducers 1620(I) and 1620(J) may be positioned on neckband 1605, thereby increasing the distance between the neckband acoustic transducers 1620(I) and 1620(J) and other acoustic transducers 1620 positioned on eyewear device 1602. In some cases, increasing the distance between acoustic transducers 1620 of the microphone array may improve the accuracy of beamforming performed via the microphone array. For example, if a sound is detected by acoustic transducers 1620(C) and 1620(D) and the distance between acoustic transducers 1620(C) and 1620(D) is greater than, e.g., the distance between acoustic transducers 1620(D) and 1620(E), the determined source location of the detected sound may be more accurate than if the sound had been detected by acoustic transducers 1620(D) and 1620(E).

Controller 1625 of neckband 1605 may process information generated by the sensors on neckband 1605 and/or augmented-reality system 1600. For example, controller 1625 may process information from the microphone array that describes sounds detected by the microphone array. For each detected sound, controller 1625 may perform a direction-of-arrival (DOA) estimation to estimate a direction from which the detected sound arrived at the microphone array. As the microphone array detects sounds, controller 1625 may populate an audio data set with the information. In embodiments in which augmented-reality system 1600 includes an inertial measurement unit, controller 1625 may compute all inertial and spatial calculations from the IMU located on eyewear device 1602. A connector may convey information between augmented-reality system 1600 and neckband 1605 and between augmented-reality system 1600 and controller 1625. The information may be in the form of optical data, electrical data, wireless data, or any other transmittable data form. Moving the processing of information generated by augmented-reality system 1600 to neckband 1605 may reduce weight and heat in eyewear device 1602, making it more comfortable to the user.

Power source 1635 in neckband 1605 may provide power to eyewear device 1602 and/or to neckband 1605. Power source 1635 may include, without limitation, lithium ion batteries, lithium-polymer batteries, primary lithium batteries, alkaline batteries, or any other form of power storage. In some cases, power source 1635 may be a wired power source. including power source 1635 on neckband 1605 instead of on eyewear device 1602 may help better distribute the weight and heat generated by power source 1635.

As noted, some artificial-reality systems may, instead of blending an artificial reality with actual reality, substantially replace one or more of a user's sensory perceptions of the real world with a virtual experience. One example of this type of system is a head-worn display system, such as virtual-reality system 1700 in FIG. 17, that mostly or completely covers a user's field of view. Virtual-reality system 1700 may include a front rigid body 1702 and a band 1704 shaped to fit around a user's head. Virtual-reality system 1700 may also include output audio transducers 1706(A) and 1706(B). Furthermore, while not shown in FIG. 17, front rigid body 1702 may include one or more electronic elements, including one or more electronic displays, one or more inertial measurement units (IMUS), one or more tracking emitters or detectors, and/or any other suitable device or system for creating an artificial-reality experience.

Artificial-reality systems may include a variety of types of visual feedback mechanisms. For example, display devices in augmented-reality system 1600 and/or virtual-reality system 1700 may include one or more liquid crystal displays (LCDs), light emitting diode (LED) displays, microLED displays, organic LED (OLED) displays, digital light project (DLP) micro-displays, liquid crystal on silicon (LCoS) micro-displays, and/or any other suitable type of display screen. These artificial-reality systems may include a single display screen for both eyes or may provide a display screen for each eye, which may allow for additional flexibility for varifocal adjustments or for correcting a user's refractive error. Some of these artificial-reality systems may also include optical subsystems having one or more lenses (e.g., concave or convex lenses, Fresnel lenses, adjustable liquid lenses, etc.) through which a user may view a display screen. These optical subsystems may serve a variety of purposes, including to collimate (e.g., make an object appear at a greater distance than its physical distance), to magnify (e.g., make an object appear larger than its actual size), and/or to relay (to, e.g., the viewer's eyes) light. These optical subsystems may be used in a non-pupil-forming architecture (such as a single lens configuration that directly collimates light but results in so-called pincushion distortion) and/or a pupil-forming architecture (such as a multi-lens configuration that produces so-called barrel distortion to nullify pincushion distortion).

In addition to or instead of using display screens, some of the artificial-reality systems described herein may include one or more projection systems. For example, display devices in augmented-reality system 1600 and/or virtual-reality system 1700 may include micro-LED projectors that project light (using, e.g., a waveguide) into display devices, such as clear combiner lenses that allow ambient light to pass through. The display devices may refract the projected light toward a user's pupil and may enable a user to simultaneously view both artificial-reality content and the real world. The display devices may accomplish this using any of a variety of different optical components, including waveguide components (e.g., holographic, planar, diffractive, polarized, and/or reflective waveguide elements), light-manipulation surfaces and elements (such as diffractive, reflective, and refractive elements and gratings), coupling elements, etc. Artificial-reality systems may also be configured with any other suitable type or form of image projection system, such as retinal projectors used in virtual retina displays.

The artificial-reality systems described herein may also include various types of computer vision components and subsystems. For example, augmented-reality system 1600 and/or virtual-reality system 1700 may include one or more optical sensors, such as two-dimensional (2D) or 3D cameras, structured light transmitters and detectors, time-of-flight depth sensors, single-beam or sweeping laser rangefinders, 3D LiDAR sensors, and/or any other suitable type or form of optical sensor. An artificial-reality system may process data from one or more of these sensors to identify a location of a user, to map the real world, to provide a user with context about real-world surroundings, and/or to perform a variety of other functions.

The artificial-reality systems described herein may also include one or more input and/or output audio transducers. Output audio transducers may include voice coil speakers, ribbon speakers, electrostatic speakers, piezoelectric speakers, bone conduction transducers, cartilage conduction transducers, tragus-vibration transducers, and/or any other suitable type or form of audio transducer. Similarly, input audio transducers may include condenser microphones, dynamic microphones, ribbon microphones, and/or any other type or form of input transducer. In some embodiments, a single transducer may be used for both audio input and audio output.

In some embodiments, the artificial-reality systems described herein may also include tactile (i.e., haptic) feedback systems, which may be incorporated into headwear, gloves, body suits, handheld controllers, environmental devices (e.g., chairs, floormats, etc.), and/or any other type of device or system. Haptic feedback systems may provide various types of cutaneous feedback, including vibration, force, traction, texture, and/or temperature. Haptic feedback systems may also provide various types of kinesthetic feedback, such as motion and compliance. Haptic feedback may be implemented using motors, piezoelectric actuators, fluidic systems, and/or a variety of other types of feedback mechanisms. Haptic feedback systems may be implemented independent of other artificial-reality devices, within other artificial-reality devices, and/or in conjunction with other artificial-reality devices.

By providing haptic sensations, audible content, and/or visual content, artificial-reality systems may create an entire virtual experience or enhance a user's real-world experience in a variety of contexts and environments. For instance, artificial-reality systems may assist or extend a user's perception, memory, or cognition within a particular environment. Some systems may enhance a user's interactions with other people in the real world or may enable more immersive interactions with other people in a virtual world. Artificial-reality systems may also be used for educational purposes (e.g., for teaching or training in schools, hospitals, government organizations, military organizations, business enterprises, etc.), entertainment purposes (e.g., for playing video games, listening to music, watching video content, etc.), and/or for accessibility purposes (e.g., as hearing aids, visual aids, etc.). The embodiments disclosed herein may enable or enhance a user's artificial-reality experience in one or more of these contexts and environments and/or in other contexts and environments.

As noted, artificial-reality systems 1600 and 1700 may be used with a variety of other types of devices to provide a more compelling artificial-reality experience. These devices may be haptic interfaces with transducers that provide haptic feedback and/or that collect haptic information about a user's interaction with an environment. The artificial-reality systems disclosed herein may include various types of haptic interfaces that detect or convey various types of haptic information, including tactile feedback (e.g., feedback that a user detects via nerves in the skin, which may also be referred to as cutaneous feedback) and/or kinesthetic feedback (e.g., feedback that a user detects via receptors located in muscles, joints, and/or tendons).

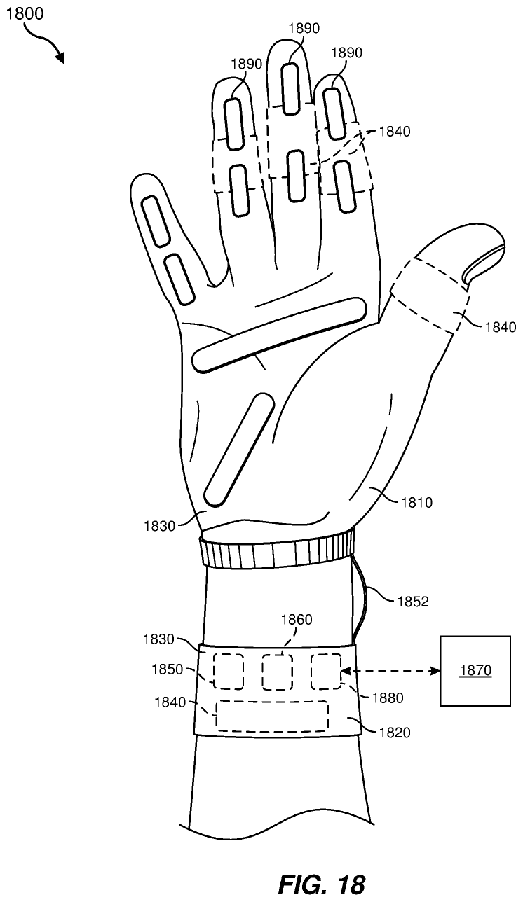

Haptic feedback may be provided by interfaces positioned within a user's environment (e.g., chairs, tables, floors, etc.) and/or interfaces on articles that may be worn or carried by a user (e.g., gloves, wristbands, etc.). As an example, FIG. 18 illustrates a vibrotactile system 1800 in the form of a wearable glove (haptic device 1810) and wristband (haptic device 1820). Haptic device 1810 and haptic device 1820 are shown as examples of wearable devices that include a flexible, wearable textile material 1830 that is shaped and configured for positioning against a user's hand and wrist, respectively. This disclosure also includes vibrotactile systems that may be shaped and configured for positioning against other human body parts, such as a finger, an arm, a head, a torso, a foot, or a leg. By way of example and not limitation, vibrotactile systems according to various embodiments of the present disclosure may also be in the form of a glove, a headband, an armband, a sleeve, a head covering, a sock, a shirt, or pants, among other possibilities. In some examples, the term “textile” may include any flexible, wearable material, including woven fabric, non-woven fabric, leather, cloth, a flexible polymer material, composite materials, etc.

One or more vibrotactile devices 1840 may be positioned at least partially within one or more corresponding pockets formed in textile material 1830 of vibrotactile system 1800. Vibrotactile devices 1840 may be positioned in locations to provide a vibrating sensation (e.g., haptic feedback) to a user of vibrotactile system 1800. For example, vibrotactile devices 1840 may be positioned against the user's finger(s), thumb, or wrist, as shown in FIG. 18. Vibrotactile devices 1840 may, in some examples, be sufficiently flexible to conform to or bend with the user's corresponding body part(s).

A power source 1850 (e.g., a battery) for applying a voltage to the vibrotactile devices 1840 for activation thereof may be electrically coupled to vibrotactile devices 1840, such as via conductive wiring 1852. In some examples, each of vibrotactile devices 1840 may be independently electrically coupled to power source 1850 for individual activation. In some embodiments, a processor 1860 may be operatively coupled to power source 1850 and configured (e.g., programmed) to control activation of vibrotactile devices 1840.

Vibrotactile system 1800 may be implemented in a variety of ways. In some examples, vibrotactile system 1800 may be a standalone system with integral subsystems and components for operation independent of other devices and systems. As another example, vibrotactile system 1800 may be configured for interaction with another device or system 1870. For example, vibrotactile system 1800 may, in some examples, include a communications interface 1880 for receiving and/or sending signals to the other device or system 1870. The other device or system 1870 may be a mobile device, a gaming console, an artificial-reality (e.g., virtual-reality, augmented-reality, mixed-reality) device, a personal computer, a tablet computer, a network device (e.g., a modem, a router, etc.), a handheld controller, etc. Communications interface 1880 may enable communications between vibrotactile system 1800 and the other device or system 1870 via a wireless (e.g., Wi-Fi, BLUETOOTH, cellular, radio, etc.) link or a wired link. If present, communications interface 1880 may be in communication with processor 1860, such as to provide a signal to processor 1860 to activate or deactivate one or more of the vibrotactile devices 1840.

Vibrotactile system 1800 may optionally include other subsystems and components, such as touch-sensitive pads 1890, pressure sensors, motion sensors, position sensors, lighting elements, and/or user interface elements (e.g., an on/off button, a vibration control element, etc.). During use, vibrotactile devices 1840 may be configured to be activated for a variety of different reasons, such as in response to the user's interaction with user interface elements, a signal from the motion or position sensors, a signal from the touch-sensitive pads 1890, a signal from the pressure sensors, a signal from the other device or system 1870, etc.

Although power source 1850, processor 1860, and communications interface 1880 are illustrated in FIG. 18 as being positioned in haptic device 1820, the present disclosure is not so limited. For example, one or more of power source 1850, processor 1860, or communications interface 1880 may be positioned within haptic device 1810 or within another wearable textile.

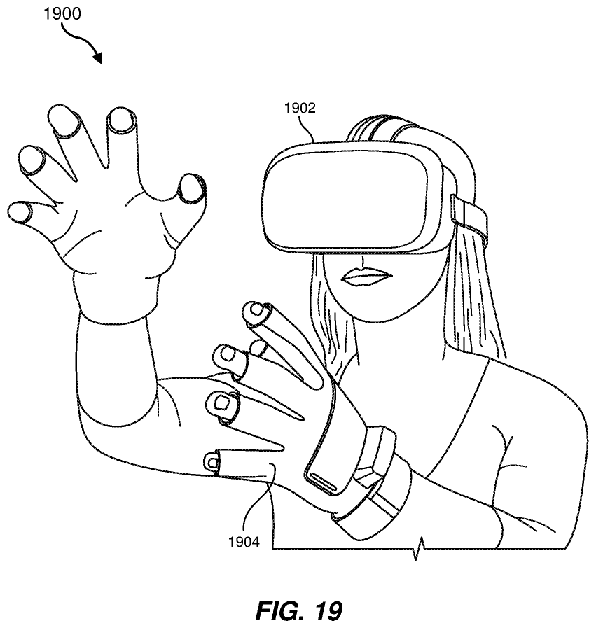

Haptic wearables, such as those shown in and described in connection with FIG. 18, may be implemented in a variety of types of artificial-reality systems and environments. FIG. 19 shows an example artificial-reality environment 1900 including one head-mounted virtual-reality display and two haptic devices (i.e., gloves), and in other embodiments any number and/or combination of these components and other components may be included in an artificial-reality system. For example, in some embodiments there may be multiple head-mounted displays each having an associated haptic device, with each head-mounted display and each haptic device communicating with the same console, portable computing device, or other computing system.

Head-mounted display 1902 generally represents any type or form of virtual-reality system, such as virtual-reality system 1700 in FIG. 17. Haptic device 1904 generally represents any type or form of wearable device, worn by a user of an artificial-reality system, that provides haptic feedback to the user to give the user the perception that he or she is physically engaging with a virtual object. In some embodiments, haptic device 1904 may provide haptic feedback by applying vibration, motion, and/or force to the user. For example, haptic device 1904 may limit or augment a user's movement. To give a specific example, haptic device 1904 may limit a user's hand from moving forward so that the user has the perception that his or her hand has come in physical contact with a virtual wall. In this specific example, one or more actuators within the haptic device may achieve the physical-movement restriction by pumping fluid into an inflatable bladder of the haptic device. In some examples, a user may also use haptic device 1904 to send action requests to a console. Examples of action requests include, without limitation, requests to start an application and/or end the application and/or requests to perform a particular action within the application.

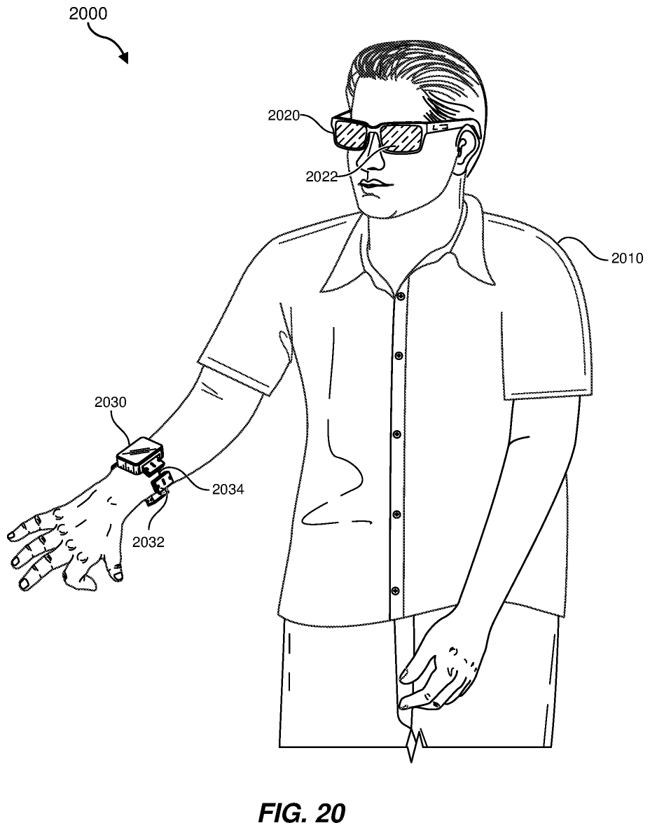

While haptic interfaces may be used with virtual-reality systems, as shown in FIG. 19, haptic interfaces may also be used with augmented-reality systems, as shown in FIG. 20. FIG. 20 is a perspective view of a user 2010 interacting with an augmented-reality system 2000. In this example, user 2010 may wear a pair of augmented-reality glasses 2020 that may have one or more displays 2022 and that are paired with a haptic device 2030. In this example, haptic device 2030 may be a wristband that includes a plurality of band elements 2032 and a tensioning mechanism 2034 that connects band elements 2032 to one another.

One or more of band elements 2032 may include any type or form of actuator suitable for providing haptic feedback. For example, one or more of band elements 2032 may be configured to provide one or more of various types of cutaneous feedback, including vibration, force, traction, texture, and/or temperature. To provide such feedback, band elements 2032 may include one or more of various types of actuators. In one example, each of band elements 2032 may include a vibrotactor (e.g., a vibrotactile actuator) configured to vibrate in unison or independently to provide one or more of various types of haptic sensations to a user. Alternatively, only a single band element or a subset of band elements may include vibrotactors.

Haptic devices 1810, 1820, 1904, and 2030 may include any suitable number and/or type of haptic transducer, sensor, and/or feedback mechanism. For example, haptic devices 1810, 1820, 1904, and 2030 may include one or more mechanical transducers, piezoelectric transducers, and/or fluidic transducers. Haptic devices 1810, 1820, 1904, and 2030 may also include various combinations of different types and forms of transducers that work together or independently to enhance a user's artificial-reality experience. In one example, each of band elements 2032 of haptic device 2030 may include a vibrotactor (e.g., a vibrotactile actuator) configured to vibrate in unison or independently to provide one or more of various types of haptic sensations to a user.

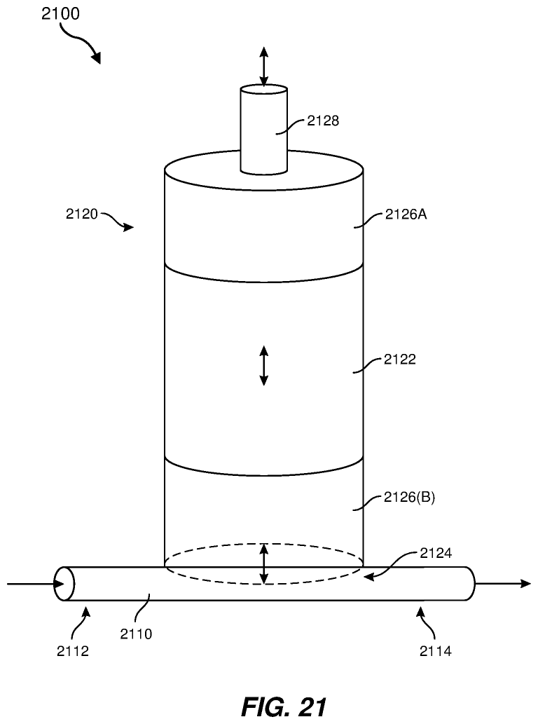

As noted above, the present disclosure may also include haptic fluidic systems that involve the control (e.g., stopping, starting, restricting, increasing, etc.) of fluid flow through a fluid channel. The control of fluid flow may be accomplished with a fluidic valve. FIG. 21 shows a schematic diagram of a fluidic valve 2100 for controlling flow through a fluid channel 2110, according to at least one embodiment of the present disclosure. Fluid from a fluid source (e.g., a pressurized fluid source, a fluid pump, etc.) may flow through the fluid channel 2110 from an inlet port 2112 to an outlet port 2114, which may be operably coupled to, for example, a fluid-driven mechanism, another fluid channel, or a fluid reservoir.

Fluidic valve 2100 may include a gate 2120 for controlling the fluid flow through fluid channel 2110. Gate 2120 may include a gate transmission element 2122, which may be a movable component that is configured to transmit an input force, pressure, or displacement to a restricting region 2124 to restrict or stop flow through the fluid channel 2110. Conversely, in some examples, application of a force, pressure, or displacement to gate transmission element 2122 may result in opening restricting region 2124 to allow or increase flow through the fluid channel 2110. The force, pressure, or displacement applied to gate transmission element 2122 may be referred to as a gate force, gate pressure, or gate displacement. Gate transmission element 2122 may be a flexible element (e.g., an elastomeric membrane, a diaphragm, etc.), a rigid element (e.g., a movable piston, a lever, etc.), or a combination thereof (e.g., a movable piston or a lever coupled to an elastomeric membrane or diaphragm).

As illustrated in FIG. 21, gate 2120 of fluidic valve 2100 may include one or more gate terminals, such as an input gate terminal 2126(A) and an output gate terminal 2126(B) (collectively referred to herein as “gate terminals 2126”) on opposing sides of gate transmission element 2122. Gate terminals 2126 may be elements for applying a force (e.g., pressure) to gate transmission element 2122. By way of example, gate terminals 2126 may each be or include a fluid chamber adjacent to gate transmission element 2122. Alternatively or additionally, one or more of gate terminals 2126 may include a solid component, such as a lever, screw, or piston, that is configured to apply a force to gate transmission element 2122.

In some examples, a gate port 2128 may be in fluid communication with input gate terminal 2126(A) for applying a positive or negative fluid pressure within the input gate terminal 2126(A). A control fluid source (e.g., a pressurized fluid source, a fluid pump, etc.) may be in fluid communication with gate port 2128 to selectively pressurize and/or depressurize input gate terminal 2126(A). In additional embodiments, a force or pressure may be applied at the input gate terminal 2126(A) in other ways, such as with a piezoelectric element or an electromechanical actuator, etc.

In the embodiment illustrated in FIG. 21, pressurization of the input gate terminal 2126(A) may cause the gate transmission element 2122 to be displaced toward restricting region 2124, resulting in a corresponding pressurization of output gate terminal 2126(B). Pressurization of output gate terminal 2126(B) may, in turn, cause restricting region 2124 to partially or fully restrict to reduce or stop fluid flow through the fluid channel 2110. Depressurization of input gate terminal 2126(A) may cause gate transmission element 2122 to be displaced away from restricting region 2124, resulting in a corresponding depressurization of the output gate terminal 2126(B). Depressurization of output gate terminal 2126(B) may, in turn, cause restricting region 2124 to partially or fully expand to allow or increase fluid flow through fluid channel 2110. Thus, gate 2120 of fluidic valve 2100 may be used to control fluid flow from inlet port 2112 to outlet port 2114 of fluid channel 2110.

The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed. The various exemplary methods described and/or illustrated herein may also omit one or more of the steps described or illustrated herein or include additional steps in addition to those disclosed.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the present disclosure. The embodiments disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.”Finally, for ease of use, the terms “including” and “having” (and their derivatives), as used in the specification and claims, are interchangeable with and have the same meaning as the word “comprising.”

It will be understood that when an element such as a layer or a region is referred to as being formed on, deposited on, or disposed “on” or “over” another element, it may be located directly on at least a portion of the other element, or one or more intervening elements may also be present. In contrast, when an element is referred to as being “directly on” or “directly over” another element, it may be located on at least a portion of the other element, with no intervening elements present.

As used herein, the term “approximately” in reference to a particular numeric value or range of values may, in certain embodiments, mean and include the stated value as well as all values within 10% of the stated value. Thus, by way of example, reference to the numeric value “50” as “approximately 50” may, in certain embodiments, include values equal to 50±5, i.e., values within the range 45 to 55.

As used herein, the term “substantially” in reference to a given parameter, property, or condition may mean and include to a degree that one of ordinary skill in the art would understand that the given parameter, property, or condition is met with a small degree of variance, such as within acceptable manufacturing tolerances. By way of example, depending on the particular parameter, property, or condition that is substantially met, the parameter, property, or condition may be at least approximately 90% met, at least approximately 95% met, or even at least approximately 99% met.

While various features, elements or steps of particular embodiments may be disclosed using the transitional phrase “comprising,” it is to be understood that alternative embodiments, including those that may be described using the transitional phrases “consisting” or “consisting essentially of,” are implied. Thus, for example, implied alternative embodiments to a piezoelectric membrane that comprises or includes polyvinylidene fluoride include embodiments where a piezoelectric membrane consists essentially of polyvinylidene fluoride and embodiments where a piezoelectric membrane consists of polyvinylidene fluoride.

What is claimed is:

1. A fluid pump comprising:
a housing defining a fluid chamber; and
a piezoelectric membrane attached to the housing and located within the fluid chamber, the piezoelectric membrane dividing the fluid chamber into a first fluid cavity and a second fluid cavity.

2. The fluid pump of claim 1, wherein the piezoelectric membrane comprises polyvinylidene fluoride (PVDF).

3. The fluid pump of claim 2, wherein the piezoelectric membrane comprises a particulate or fibrous piezoelectric ceramic.

4. The fluid pump of claim 1, wherein the piezoelectric membrane has an in-plane elastic modulus of at least approximately 1 GPa.

5. The fluid pump of claim 1, wherein the piezoelectric membrane is movable between a first position and a second position relative to the housing.

6. The fluid pump of claim 1, wherein the piezoelectric membrane is configured to oscillate relative to the housing.

7. The fluid pump of claim 1, further comprising an inlet port for adding fluid to the fluid chamber and an outlet port for removing fluid from the fluid chamber.

8. The fluid pump of claim 7, wherein the inlet port and the outlet port each comprise a one-way valve.

9. The fluid pump of claim 1, wherein the piezoelectric membrane is configured as a unimorph actuator.

10. The fluid pump of claim 1, wherein the piezoelectric membrane is configured as a bimorph actuator.

11. The fluid pump of claim 1, wherein the piezoelectric membrane is bi-stable.

12. A fluid pump comprising:
a housing having an opening, the housing defining a fluid chamber; and
a piezoelectric membrane attached to the housing and extending over the opening.

13. The fluid pump of claim 12, wherein the piezoelectric membrane comprises polyvinylidene fluoride (PVDF).

14. The fluid pump of claim 12, further comprising an inlet port for adding fluid to the fluid chamber and an outlet port for removing fluid from the fluid chamber.

15. The fluid pump of claim 14, wherein the inlet port and the outlet port each comprise a one-way valve.

16. The fluid pump of claim 12, wherein the piezoelectric membrane is bi-stable.

17. A method comprising:
applying an electric field to a piezoelectric membrane to oscillate the piezoelectric membrane, wherein the oscillating piezoelectric membrane applies a force to a fluid in an amount effective to displace the fluid.

18. The method of claim 17, wherein the piezoelectric membrane oscillates at a resonant frequency.

19. The method of claim 17, wherein the piezoelectric membrane directly contacts the fluid.

20. The method of claim 17, wherein the piezoelectric membrane comprises polyvinylidene fluoride (PVDF).
